(19) United States
(12) Patent Application Publication
(10) Pub. No.: US 2008/0070340 A1
(43) Pub. Date: Mar. 20, 2008

(54) Image sensor using thin-film SOI

(76) Inventors: Nicholas Francis Borrelli, Elmira, NY (US); Michael Donavon Brady, Painted Post, NY (US); Ronald Lee Burt, Painted Post, NY (US); Kishor Purushottam Gadkaree, Big Flats, NY (US)

Correspondence Address: CORNING INCORPORATED, SP-TI-3-1, CORNING, NY, 14831, US

(21) Appl. No.: 11/520,958

(22) Filed: Sep. 14, 2006

(51) Int. Cl. H01L 21/00

(52) U.S. Cl. 438/57

(57) ABSTRACT

Systems and methods related to an image sensor of one or more embodiments include subjecting a donor semiconductor wafer to an ion implantation process to create an exfoliation layer of semiconductor film on the donor semiconductor wafer, forming an anodic bond between the exfoliation layer and an insulator substrate by means of electrolysis; separating the exfoliation layer from the donor semiconductor wafer to transfer the exfoliation layer to the insulator substrate; and creating a plurality of image sensor features proximate to the exfoliation layer. Forming the anodic bonding by electrolysis may include the application of heat, pressure and voltage to the insulator structure and the exfoliation layer attached to the donor semiconductor wafer. Image sensor devices include an insulator structure, a semiconductor film, an anodic bond between them, and a plurality of image sensor features. The semiconductor film preferably comprises an exfoliation layer of a substantially single-crystal donor semiconductor wafer.

### BACKGROUND

1. Field of Invention

The present invention relates to the systems, methods and apparatus relating to an image sensor, preferably having a substantially single crystal thin film, using improved processes, including in particular transferring and anodic bonding of a semiconductor layer to an insulator substrate.

2. Description of Related Art

Digital imaging has become a key technology in recent years with applications in consumer, industrial, scientific and medical imaging markets. Solid state image sensors are used in video cameras, X-ray equipment and scientific applications, such the Hubble telescope. The two main imaging technologies are based basically on the same principles, i.e., photovoltaic response of semiconductors when exposed to photons in the visible and near IR regions of the spectrum. The number of electrons released is proportional to light intensity.

Image sensors are a specialized form of semiconductor structure, such as a semiconductor-on-insulator (SOI) structure, that converts photons into accumulated charge. Generally, image sensing involves photogeneration of charge carriers (electrons and holes) in a light-absorbing material, separation of the charge carriers to a conductive contact that will transmit the charge, and measurement of the charge. Image sensors typically fall into one of two types: charge coupled devices (CCD) and active pixel sensors (APS) based on complementary-symmetry/metal-oxide semiconductor (CMOS) technology.

In the case of a photodiode of an APS, a pixel of an image sensor commonly is configured as a p-n junction (“p” denoting positive, “n” denoting negative). A p-n junction functionally is a layer of n-type semiconductor, e.g., silicon, in direct contact with a layer of p-type semiconductor. In the case of a capacitor of a CCD, a variation of either a p-n or p-i-n configuration is common, where “i” here refers to “intrinsic” semiconductor separating the p-type and n-type layers, as a buffer. A layer of insulator may be used to act as a dielectric. In practice, a p-n junction is made by diffusing an n-type dopant into one side of a p-type wafer (or vice versus).

Referring to FIGS. A, B, C and D, block diagrams illustrate prior art, front-side illuminated image sensor configurations, respectively, of a well-substrate junction diode, a diffusion-well diode, a bidirectional photodetector, and a photogate. With a piece of p-type silicon in intimate contact with a piece of n-type silicon, incident light causes a diffusion of electrons from the region of high electron concentration (the n-type side of the junction) into the region of low electron concentration (p-type side of the junction). When the electrons diffuse across the p-n junction, they recombine with holes on the p-type side.

This diffusion creates an electric field by the imbalance of charge immediately on either side of the junction. The electric field established across the p-n junction creates a diode that promotes current to flow in only one direction across the junction. Electrons may pass from the n-type side into the p-type side, and holes may pass from the p-type side to the n-type side. This region where electrons have diffused across the junction is called the depletion region because it no longer contains any mobile charge carriers. It is also known as the “space charge region”.

Image sensors share many of the same processing and manufacturing techniques with other semiconductor devices such as computer and memory chips. To date, the semiconductor material most commonly used in such semiconductor-on-insulator (SOI) structures has been silicon. Such structures have been referred to in the literature as silicon-on-insulator structures and the abbreviation “SOI” has been applied to such structures as well. SOI technology is becoming increasingly important not only for image sensors, but also for high performance thin film transistors, and displays, such as active matrix displays. SOI structures may include a thin layer of substantially single-crystal silicon (generally 0.05-0.3 microns (50-300 nm) in thickness but, in some cases, as thick as 5 microns (5000 nm) on an insulating material.

The primary issues with the use of bulk Si are the cost and supply of high grade silicon and its utilization. One large-scale commercial technique is to make screen printed poly-crystalline silicon chips. However, poly-crystalline silicon is disadvantageous for image sensors. With a typical bulk crystal-Si or p-Si chip of 200 microns thick, the kerf loss from cutting wafers from boules or cast ingots is approximately 30%, significantly contributing to the overall cost. Single crystalline wafers which are used in the semiconductor industry can be made into excellent image sensors, but expense is a major concern for large-scale mass production.

Thus, the use of thin films is of particular interest from a cost perspective. Thin-film image sensors use less than 1% of the raw material (silicon or other light absorbers) compared to traditional wafer-based image sensors. One particularly promising technology is crystalline silicon thin films on glass substrates. This technology makes use of the advantages of crystalline silicon as a photoelectric material, with the cost savings of using a thin-film approach. To wit, none of the aforementioned structures on low-cost, glass substrates have led to image sensors. Hence, a process and product directed to image sensors based on a low-cost and transparent glass substrates are desired that overcome the issues associated with prior art.

The challenges of thin film use vary depending on the particular technology. The various thin-film technologies currently being developed reduce the amount (or mass) of light-absorbing material required in creating an image sensor. This can lead to reduced processing costs from that of bulk materials (in the case of silicon thin films) By contrast, manufacturing image sensors using wire-sawing bulk Si results in significant waste of prepared Si.

Considering that some improvements to microelectronic manufacturing may be applied, with some modification, to image sensor manufacturing, it is therefore desirable to identify novel modified semiconductor manufacturing techniques applicable to image sensors that may provide advantages specific to image sensors, such as increased fill factor, quantum efficiency and reduced cost.

In the microelectronic semiconductor world, devices often are called semiconductor-on-insulator (SOI) structures, for ease of discussion. As used here, reference to SOI structures is made to facilitate the explanation of the technology and is not intended to, and should not be interpreted as, limiting the invention's scope in any way. The SOI abbreviation is used herein to refer to semiconductor-on-insulator structures in general, including, but not limited to, silicon-on-insulator structures, such as silicon-on-glass (SiOG) structures. Similarly, the SiOG abbreviation is used to refer to semiconductor-on-glass structures in general, including, but not limited to, silicon-on-glass structures. The SiOG nomenclature is also intended to include semiconductor-on-glass-ceramic structures, including, but not limited to, silicon-on-glass-ceramic structures. The abbreviation SOI encompasses SiOG structures.

Various ways of obtaining SOI-structure wafers include (1) epitaxial growth of silicon (Si) on lattice-matched substrates; (2) bonding of a single-crystal silicon wafer to another silicon wafer on which an oxide layer of SiO₂ has been grown, followed by polishing or etching of the top wafer down to, for example, a 0.05 to 0.3 micron (50-300 nm) layer of single-crystal silicon; and (3) ion-implantation methods, in which either hydrogen or oxygen ions are implanted, either to form a buried oxide layer in the silicon wafer topped by Si, in the case of oxygen ion implantation, or to separate (exfoliate) a thin Si layer from one silicon wafer for bonding to another Si wafer with an oxide layer, as in the case of hydrogen ion implantation.

The former two methods, epitaxial growth and wafer-wafer bonding, have not resulted in satisfactory structures in terms of cost and/or bond strength and durability. The latter method involving ion implantation has received some attention, and, in particular, hydrogen ion implantation has been considered advantageous because the implantation energies required are typically less than 50% of that of oxygen ion implants and the dosage required is two orders of magnitude lower.

For instance, a thermal-bond exfoliation process may be used to obtain an exfoliated single-crystal silicon film thermally bonded to a substrate. Such a thermal-bond exfoliation process includes subjecting a silicon wafer having a planar face to the following steps: (i) implantation by bombardment of a face of the silicon wafer by means of ions creating a layer of gaseous micro-bubbles defining a lower region of the silicon wafer and an upper region constituting a thin silicon film; (ii) contacting the planar face of the silicon wafer with a rigid material layer (such as an insulating oxide material); and (iii) a third stage of heat treating the assembly of the silicon wafer and the insulating material at a temperature above that at which the ion bombardment was carried out. The third stage employs temperatures sufficient to bond the thin silicon film and the insulating material together, to create a pressure effect in the micro-bubbles, and to cause an exfoliation separation between the thin silicon film and the remaining mass of the silicon wafer. However, due to the high temperature steps, this process is not compatible with lower-cost glass or glass-ceramic substrates.

It would therefore be desirable to incorporate the advantages of SOI structure manufacturing advances with the requirements of the image sensor manufacturing, while minimizing the disadvantages of the associated SOI structure manufacturing advances.

### SUMMARY OF THE INVENTION

In accordance with one or more embodiments of the present invention, systems, methods and apparatus of forming an image sensor device include creating an exfoliation layer and transferring it to an insulator structure. The exfoliation layer may be created from a donor semiconductor wafer. The donor semiconductor wafer and the exfoliation layer preferably may comprise substantially single-crystal semiconductor material. The exfoliation layer preferably may include one or more image sensor features or regions, such as a conductive layer, created prior to transfer to the insulator substrate.

Transferring the exfoliation layer preferably may include: forming, by electrolysis, an anodic bond between the exfoliation layer and the insulator substrate, and then separating the exfoliation layer from the donor semiconductor wafer using thermo-mechanical stress. Separating the exfoliation layer may thereby expose at least one cleaved surface. At least one image sensor feature or region also may be created in, on or above the exfoliation layer after the exfoliation layer has been transferred to the insulator substrate. One or more finishing processes may be performed before or after transferring the exfoliation layer. Performance of a finishing process may create an image sensor feature. For instance, the at least one cleaved surface may be subjected to at least one finishing process, which preferably may create one or more image sensor features.

Creating an exfoliation layer may include subjecting an implantation surface of a donor semiconductor wafer to an ion implantation process. Creating an exfoliation layer further may include using one or more finishing processes, such as to clean the exfoliation layer before bonding or to create at least one image sensor feature before bonding. Creating an image sensor feature before bonding may occur before or after subjecting the implantation surface to an ion implantation process.

In one or more embodiments, the step of bonding may include: heating at least one of the insulator substrate and the donor semiconductor wafer; bringing the insulator substrate into direct or indirect contact with the exfoliation layer of the donor semiconductor wafer; and applying a voltage potential across the insulator substrate and the donor semiconductor wafer to induce the bond. The temperature of the insulator substrate and the semiconductor wafer may be elevated to within about 150 degrees C. of the strain point of the insulator substrate. The temperatures of the insulator substrate and the semiconductor wafer may be elevated to different levels. The voltage potential across the insulator substrate and the semiconductor wafer may be between about 100 to 10000 volts.

Separating the exfoliation layer from the donor semiconductor wafer may be done using stress induced by cooling the bonded insulator substrate, exfoliation layer, and donor semiconductor wafer such that a fracture occurs substantially at an ion implantation zone defining a boundary of the exfoliation layer within the donor semiconductor wafer. The heating and cooling, paired with the differential coefficient of thermal expansion of the ion implantation zone versus that of the surrounding wafer, cause the exfoliation layer to cleave at the ion implantation zone and separate from the donor semiconductor wafer. The result is a thin film of semiconductor bonded to the insulator.

The at least one cleaved surface may include a first cleaved surface of the donor semiconductor wafer and a second cleaved surface of the exfoliation layer. With respect to the first cleaved surface associated with donor semiconductor wafer, the finishing process may include preparing the donor semiconductor wafer for reuse. With respect to the second cleaved surface associated with exfoliated layer, the finishing process may include completing the image sensor device.

According to one or more preferred embodiments of the present invention, new image sensors may be based on single crystal Ge, Si or GaAs films on transparent glass or glass ceramic substrates. In the case of GaAs-based sensors, as an added advantage, a germanium layer may be present between the substrate and the single crystalline GaAs layer. The germanium layer may be doped in order to use the substrate as a bottom layer (i.e., back contact layer) of a multi-junction image sensor. The glass or glass ceramic substrates may be expansion matched to Ge, Si, GaAs or Ge/GaAs. The strongly adherent single crystal layer of Si, Ge, GaAs or Ge/GaAs film may be obtained on the glass or glass ceramic substrate via an electrolysis-based anodic bonding process described in U.S. Patent Application Publication No. 2004/0229444.

The process first involves hydrogen or hydrogen and helium implantation of the semiconductor wafer, e.g., Ge, Si or GaAs wafer, and in the case of GaAs, possibly followed by deposition of a germanium film on the surface of the GaAs wafer. Because of their greater bandgap, silicon-based photodiodes generate less imaging noise than germanium-based photodiodes, but germanium photodiodes must be used for wavelengths longer than approximately 1 μm. The Ge, Si or Ge-coated GaAs wafer is then bonded to the glass substrate, followed by separation of a thin film structure of Ge, Si, GaAs or GaAs/Ge. The SOG structure thus obtained may be polished to remove the damaged region and to expose the good quality single crystal layer of the semiconductor. This SOG structure may be used then as a template for subsequent epitaxial growth of multiple layers of Si, Ge, GaAS, GaInP₂, GaInAs, etc. to form desired imaging sensors. The glass, in addition to being expansion matched to the semiconductor layer also may have a strain point high enough to withstand subsequent deposition conditions.

Known image sensor architectures include numerous configurations, including p-type-intrinsic-n-type (p-i-n) junctions, metal-insulator-semiconductor (MIS) junctions, so-called “tandem” junctions, multi-junctions, and complex p-n multilayer structures, but the present invention is not limited to these structures. It is within the competency of persons of ordinary skill in the image sensor arts to create the image sensor device according to desired product characteristics, such as single-junction versus multi-junction. Similarly, whether the one or more of the image sensor features is created before or after the ion implantation or after transfer is a decision within the competency of persons of ordinary skill, taking into consideration a suitable ion penetration depth in the semiconductor material.

It is noted that the donor semiconductor wafer may be a part of structure that includes a substantially single-crystal donor semiconductor wafer and optionally includes an epitaxial semiconductor layer disposed on the donor semiconductor wafer. The exfoliation layer (e.g., the layer bonded to the insulator substrate and separated from the donor semiconductor structure) may thus be formed substantially from the single-crystal donor semiconductor wafer material. Alternatively, the exfoliation layer may be formed substantially from the epitaxial semiconductor layer (and which may also include some of the single-crystal donor semiconductor wafer material).

The advantages of this invention are best understood after reading the detailed technical description, and in relation to existing SOI processes. Nonetheless, the primary advantages include: image sensor structure variation; thinner silicon films; more uniform silicon films with higher crystal quality; faster manufacturing throughput; improved manufacturing yield; reduced contamination; and scalability to large substrates. These benefits naturally combine to reduce costs.

Image sensor structures may be varied insofar as complex structures may be made through high temperature processes on donor semiconductor wafers. The resultant high performance sensor then may be transferred to a low-cost glass substrate and completed, for instance, with deposition of remaining layers and any patterning required to complete the circuitry.

The present invention allows use of only the required thickness of semiconductor (around 10-30 microns for Si, and 1-3 microns for direct bandgap semiconductors such as GaAs). The film thickness may be selected for suitability to various MOSFET structures and various spectra of light to be imaged. In contrast to the transfer of thicker silicon films to the insulator substrate that are then polished to remove the damaged surface, control of which is difficult for very thin films, little material is removed in the process as described in this invention, allowing thin silicon films to be transferred directly, with additional thickness deposited or grown thereafter as needed. The use of thin films and the ability to control film thickness also improve the ability to control the sensitivity and selectivity of the image sensor to various light spectra and reduce noise, smear and blur.

Uniform films are very desirable. Again, because little material is removed in the process, the silicon film thickness uniformity is determined by the ion implant. This has been shown to be quite uniform, with a standard deviation of around 1 nm. In contrast, polishing typically results in a deviation in film thickness of 5% of the amount removed.

As demand continues to rise, faster throughput is critical. However, the polishing technologies identified for fabricating SiOG have process times on the order of tens of minutes, and the furnace anneals can be several hours. With more uniform films, the need in image sensors for polishing or furnace annealing is reduced.

Improving manufacturing yield is also important for waste and cost reduction. By avoiding the wire-saw kerf loss, material waste may be reduced significantly. Likewise, the expensive donor semiconductor wafer may be polished and reused multiple times. By using thin films, material consumption likewise may be reduced significantly. If polishing of the SOI structure is avoided, the overall manufacturing yield is expected to improve. This is particularly true if the polishing process has a low step yield, as anticipated. The process window is expected to be large because of the crystalline nature of the film, and therefore the yield is expected to be high.

Due to the sensitive nature of SOIs, contamination adversely may affect performance, so reducing contamination is highly desirable. With this in mind, avoiding the need for polishing with an abrasive slurry to reduce layer thickness reduces the potential for contamination. Furthermore, avoiding the need for a furnace anneal also avoids the diffusion of contaminants that may occur during a lengthy thermal anneal process. This may play an important consideration in the efficiency of the imaging devices.

The process is scalable to large areas. This scalability potentially extends the product life as customer substrate size requirements increase. Larger image sensors may provide additional resolution to maximize use of available light, which may be limited, such as in applications involving night-vision and astronomy. In contrast, surface polishing and furnace annealing become increasing difficult for larger substrate sizes.

In particular, key advantages of preferred embodiments of the present invention include: 1) the use of low-cost, expansion-matched glass or glass ceramic substrates, compared to other more expensive semiconductor films (such as silicon, as has been used previously) or thermally mismatched ceramic substrates described in the prior art; 2) the presence of the single crystal template layer of Si, Ge or multilayer GaAs/Ge on the glass substrate, which is used as a template to create lattice matched, very low defect semiconductor layers for the image sensor features with high efficiencies, unlike polycrystalline templates used in prior art; 3) the transparency of the substrate allowing flexibility in module fabrication and utilization, including improved backside illumination and quantum efficiency; 4) the lack of adhesive between the glass and the rest of the image sensor (no interference, no instability, no added steps or cost, etc.); 5) mechanical durability of the image sensor due to protection offered by the glass substrate; 6) mechanical durability of the image sensor due to the strong anodic bond between the semiconductor film and the insulator substrate; and 7) design & fabrication flexibility to achieve image sensor structures that were previously impractical or impossible.

Other aspects, features, advantages, etc. will become apparent to one skilled in the art when the description of the invention herein is taken in conjunction with the accompanying drawings.

### BRIEF DESCRIPTION OF THE DRAWINGS

For the purposes of illustrating the various aspects of the invention, wherein like numerals indicate like elements, there are shown in the drawings simplified forms that are presently preferred, it being understood, however, that the invention is not limited by or to the precise arrangements and instrumentalities shown, but rather only by the issued claims. The drawings are not to scale, nor are the aspects of the drawings to scale relative to each other.

FIGS. A, B, C and D are block diagrams illustrating prior art, front-side illuminated image sensor configurations, respectively, of a well-substrate junction diode, a diffusion-well diode, a bidirectional photodetector, and a photogate.

FIGS. 1A, 1B, 1C and 1D are block diagrams illustrating exemplary backside-illuminated image sensor configurations, respectively, of a well-substrate junction diode, a diffusion-well diode, a bidirectional photodetector, and a photogate, each in accordance with one or more embodiments of the present invention.

FIGS. 2A, 2B and 2C are flow diagrams illustrating process steps that may be carried out to produce a image sensor SOI structure in accordance with one or more embodiments of the present invention.

FIGS. 3A-C, 4A, 4B, 5A, 5B AND 6-7 are block diagrams illustrating intermediate and near-final structures formed using the processes in accordance with one or more embodiments of the present invention.

FIGS. 8A and 8B depict a flow diagram and block diagram, respectively, illustrating process steps and assemblies used in a system for formation of image sensor structures.

FIG. 9 depicts a simplified image sensor according to one or more preferred embodiments of the present invention.

### DETAILED DESCRIPTION OF THE PRESENT INVENTION

Image Sensor Types

Image sensors typically fall into one of two types: charge coupled devices (CCD) and active pixel sensors (APS) based on complementary-symmetry/metal-oxide semiconductor (CMOS) technology. A charge-coupled device (CCD) is an image sensor consisting of an integrated circuit containing an array of linked, or coupled, capacitors sensitive to light. Under the control of an external circuit, each capacitor can transfer its electric charge to one or other of its neighbors. Once the array has been exposed to the image, the control circuit causes each capacitor to transfer its contents to its neighbor. The last capacitor in the array dumps its charge into an amplifier that converts the charge into a voltage. By repeating this process, the control circuit converts the entire contents of the array to a varying voltage, which it samples, digitizes and stores in memory. Stored images can be transferred to a printer, storage device or video display.

The most common CCD architectures include full-frame, frame-transfer and interline, each of which approaches to the problem of shuttering differently. In a full-frame device, all of the image area is active, and there is no electronic shutter. A mechanical shutter must be added to this type of sensor or the image will smear as the device is clocked or read out.

With a frame transfer CCD, half of the silicon area is covered by an opaque mask (typically aluminum). The image can be quickly transferred from the image area to the opaque area or storage region with acceptable smear of a few percent. That image can then be read out slowly from the storage region while a new image is integrating or exposing the active area. Frame-transfer devices typically do not require a mechanical shutter and were a common architecture for early solid-state broadcast cameras. The downside to the frame-transfer architecture is that it requires twice the silicon surface area of an equivalent full-frame device; hence, it costs roughly twice as much.

The interline architecture extends the frame transfer concept one step further and masks every other column of the image sensor for storage. In an interline CCD, only one pixel shift has to occur to transfer from image area to storage area; thus, shutter times can be less than a microsecond and smear is essentially eliminated. The advantage is not without a cost, however, as the imaging area is now covered by opaque strips dropping the “fill factor” to approximately 50% and the effective quantum efficiency by an equivalent amount. Fill factor is the proportion of the total light reaching the image sensor that is incident to the photosensitive surface area; alternatively, fill factor is the percentage of the pixel area that is sensitive to light. Effective quantum efficiency is the proportion of the light reaching the sensor photoelectrically converted for image generation. Modern designs have addressed this deleterious characteristic by adding microlenses on the surface of the interline CCD to direct light away from the opaque regions and on the active area. Microlenses can bring the fill factor back up to 90% or more depending on pixel size and the overall system's optical design.

In contrast, an active pixel sensor (APS) is an image sensor consisting of an integrated circuit containing an array of pixels, each containing a photodetector as well as three or more transistors. The photodetector is usually a photodiode, though photogate detectors are used in some devices and can offer lower noise through the use of correlated double sampling. Light causes an accumulation, or integration of charge on the ‘parasitic’ capacitance of the photodiode, creating a voltage change related to the incident light.

The first transistor, Mᵣₛₜ, acts as a switch to reset the device. When this transistor is turned on, the photodiode effectively is connected to the power supply, V_{RST}, clearing all integrated charge. When the reset transistor is n-type, the pixel operates in soft reset. The second transistor, M_{sf}, acts as a buffer (specifically, a source follower), an amplifier which allows the pixel voltage to be observed without removing the accumulated charge. Its power supply, V_{DD}, is typically tied to the power supply of the reset transistor. The third transistor, Mₛₑₗ, is the row-select transistor. It is a switch that allows a single row of the pixel array to be read by the read-out electronics.

An APS typically has a two-dimensional array of pixels organized into rows and columns, whereby pixels in a given row share reset lines, so that a whole row is reset at a time. The row select lines of each pixel in a row also are tied together, as are the outputs of each pixel in any given column. Because only one row is selected at a given time, no competition for the output line occurs. Further amplifier circuitry is applied typically on a column basis.

To measure the charge of the image sensor, ohmic metal-semiconductor contacts are made to one or both of the n-type and p-type wells, and the electrodes connected to an external meter. Electrons that are created on the n-type side, or have been “collected” by the junction and swept onto the n-type side, may accumulate during exposure and then be output, read and reset during shuttering. Application of a reset voltage discharges the accumulated charge by causing an electron to recombine with a hole that was either created as an electron-hole pair in a p-type region, or swept across the junction from the n-type region after being created there.

Inasmuch as APS can be produced by an ordinary CMOS process, APS is emerging as an inexpensive alternative to CCDs. Since CMOS is the dominant technology for microchip manufacturing, CMOS image sensors are less expensive to make, and signal conditioning circuitry can be incorporated into the same device. The latter advantage helps mitigate the greater susceptibility of APS to noise, which is still an issue, though a diminishing one. The susceptibility of APS to noise is due to the use of low grade amplifiers in each pixel, as contrasted with the use instead of one high-grade amplifier for the entire array in the CCD. An APS also has the advantage of lower power consumption than a CCD, but a CCD has higher sensitivity and higher dynamic range than an APS. Therefore, CCDs are preferred in instances, such as astronomical imaging, where performance is of prime importance, whereas APS are preferred in consumer applications, such as camera phones, where overall cost trumps performance.

Image Sensor Structures

Image sensors commonly have a light-sensitive section and a circuitry section. Insofar as the light-sensitive section typically is formed first, it is adjacent to what is known as the back side of the image sensor. Likewise, the circuitry section often is formed later on top of the light-sensitive section, so it is adjacent to the front side on the image sensor. In front side-illuminated imaging, the light enters the front side, passes through the circuitry section, to the extent not blocked by the circuitry itself, and enters the light-sensitive section. In backside-illuminated imaging, the light enters the back side and directly enters the light-sensitive section, without the circuitry getting in the way.

Front-side imaging has been a popular technology so far, even though the circuitry obstructs the light, reducing the fill factor. CMOS technology has a disadvantage compared to CCD in front-side imaging, because of the lower quantum efficiency due to the absorption losses because of the three metal-oxide-semiconductor field-effect transistors (MOSFETs) incorporated in each pixel. Micro-lens arrays are sometimes applied to increase the fill factor by focusing incident light between the MOSFETs, but these increase device cost and have other detrimental effects on image quality.

Backside imaging has been practiced for many years also. As the performance requirements have increased, however, backside imaging technology has been developed further and may be a dominant technology of the future. Backside illumination eliminates absorption loss by producing a pixel with a potential fill factor of 100%, enabling a potential spectral response from X-ray to near-infrared (0 1-1000 mn) wavelengths. A key issue with the backside imaging is that the semiconductor film has to be very thin (−10 microns) and hence it is difficult to handle. This thinness also creates serious mechanical durability issues.

Higher fill factors generally result in higher image sensitivity. Imaging sensitivity, however, is not just how much photon-generated potential can be captured, but the signal-to-noise ratio in that captured potential. With a thick bulk Si, more electrons are generated, but many of them are noise. Some electrons are dark-current noise, which are not from photons at all, and adding more Si bulk creates more of this kind of noise. The dark current includes photocurrent generated by background radiation and the saturation current of the semiconductor junction. Dark current must be accounted for by calibration if a photodiode is used to make an accurate optical power measurement, and it is also a source of noise when a photodiode is used in an optical communication system.

Some electrons are generated from IR light which might not be desirable for a visible-light image sensor. With a thinner Si layer design, the IR spectrum can pass right through without generating noise. In applications where you do want to image the IR spectrum, you would use thicker Si. With thicker Si, it is more likely that some of the photon-generated electrons may wander into adjacent pixel sites and cause image smear or blurring.

Blurring is especially a problem in bright image areas, where there are more electrons generated than can be captured by the nearest pixels. The electrons in excess of pixel capacity spill into adjacent pixels. If the adjacent pixels are also at full capacity, the potential keeps traveling across the array until it begins to spill into darker image areas. This effect is called blooming and can be seen in digital photographs with light-bulbs or bright reflections. The image area surrounding the bright object gets washed out more than an equivalent film image would. Sometimes the focused light rays are not perpendicular to the surface, and deeper penetrating rays may end up generating electrons nearer adjacent pixels, also contributing to image smear and blur.

Image Sensor Manufacture

Image sensor technology may use bulk crystalline silicon (single crystal, crystal-Si, and cast polycrystal, p-Si) and thin film Si, achieved by deposition (CVD, LPE, PECVD, etc.) of a thin film of Si onto a substrate. The thin film may be amorphous (e.g., a-Si) or polycrystalline (e.g., p-Si, Cu—In—Se2, CdTe). According to a preferred embodiment of the present invention, the thin film is single crystal silicon.

Each type of semiconductor will have a characteristic band gap energy which, loosely speaking, causes it to absorb “light” most efficiently at a certain “color,” or more precisely, to absorb electromagnetic radiation over a portion of the spectrum. The semiconductors are carefully chosen to absorb the desired light spectrum, thus generating charge from as much of the desired light as possible, while not generating charge from undesired radiation, with the distinction between desired and undesired being dependent on the situation.

Defects in the crystal structure of the semiconductor can impede performance considerably. Significant defect reduction is achieved by “lattice matching” semiconductor layers to create similar crystal structures throughout all layers of the chip. It is possible to stack layers mechanically, but it is generally accepted as more practical and economical to grow these layers monolithically, typically by metal-organic chemical vapor deposition.

Thin film Si technology also has issues, inasmuch as the process temperatures used in the literature are near the melting point of Si, so there are considerable constraints on the substrate (purity, expansion coefficient, ability to contact the cell, etc.). In addition to Si, thin film structures may be made from other materials, including germanium (Ge), copper-indium-gallium-selenide (CIGS), copper-indium-selenide (CIS) (such as general chalcogenide films of Cu(InₓGa₁₋ₓ) (SeₓS₁₋ₓ)₂), cadmium telluride (CdTe), gallium arsenide (GaAs), and gallium indium phosphate (GaInP₂), each of which has its own issues. For example, the active layers of GaAs image sensors are only a few micrometers thick, but they must be grown on single crystal substrates. In the final product, essentially more than 95% of the material only provides passive structural support, not any imaging functionality.

Among other issues, the formation of ohmic contacts, discussed more below, to such compound semiconductors is considerably more difficult and expensive than with silicon. In the case of GaAs, GaAs surfaces tend to lose arsenic, and the trend towards As loss can be exacerbated considerably by the deposition of metal. In addition, the volatility of As limits the amount of post-deposition annealing that GaAs devices will tolerate. One solution for GaAs and other compound semiconductors is to deposit a low-bandgap alloy contact layer as opposed to a heavily doped layer. For example, GaAs itself has a smaller bandgap than AlGaAs and so a layer of GaAs near its surface can promote ohmic behavior.

In general, the technology of ohmic contacts for III-V and II-VI semiconductors is much less developed than for Si, as can be seen by the number of commonly used ohmic contact materials listed below for various semiconductor materials:

| Semiconductor | |
|---|---|
| Material | Ohmic Contact Materials |
| Si | Al, Al—Si, TiSi₂, TiN, W, MoSi₂, PtSi, CoSi₂, WSi₂ |
| Ge | In, AuGa, AuSb |
| GaAs | AuGe, PdGe, Ti/Pt/Au |
| GaN | Ti/Al/Ti/Au, Pd/Au |
| InSb | In |
| ZnO | InSnO₂, Al |
| CuIn₁₋ₓGaₓSe₂ | Mo, InSnO₂ |
| HgCdTe | In |

From a manufacturing perspective, for example, crystalline silicon wafers may be made by wire-sawing block-cast silicon ingots into very thin (250 to 350 micrometer) slices or wafers. The wafers are usually lightly p-type doped. A surface diffusion of n-type dopants is performed on the front side of the wafer. This forms a p-n junction a few hundred nanometers below the surface. Various methods of scribing, etching, depositing, doping, etc. may be used to create patterns of n-type, p-type, intrinsic and insulator regions suitable for the desired image sensor architecture, whether APS or CCD. Many image sensor configurations are known, as will be appreciated by one of ordinary skill in the art.

Antireflection coatings, which increase the amount of light coupled into the image sensor, may be applied next. Over the past decade, silicon nitride has gradually replaced titanium dioxide as the antireflection coating of choice because of its excellent surface passivation qualities (i.e., it prevents carrier recombination at the surface of the sensor). It is typically applied in a layer several hundred nanometers thick using plasma-enhanced chemical vapor deposition (PECVD).

The wafer may be metallized then, whereby a pattern of metal contacts is made on the surface, for instance using screen-printing using a metal paste, such as silver or aluminum paste. The pattern may delineate, for example, the array of pixels of the image sensor. The metal electrodes will then require some kind of heat treatment or “sintering” to make ohmic contact with the silicon, i.e., so that the current-voltage (I-V) curve of the device is linear and symmetric.

Modern ohmic contacts to silicon, such as titanium or tungsten disilicide, are usually silicides made by CVD. A silicide is a combination of silicon with more electropositive elements. An exemplary silicide might include a high temperature metal, such as tungsten, titanium, cobalt, or nickel, alloyed with silicon. Contacts are often made by first depositing the transition metal and second forming the silicide by annealing, with the result that the silicide may be non-stoichiometric. Silicide contacts can also be deposited by direct sputtering of the compound or by ion implantation of the transition metal followed by annealing.

Aluminum is another important contact metal for silicon that can be used with either the n-type or p-type semiconductor. As with other reactive metals, Al contributes to contact formation by consuming the oxygen in the native oxide. Silicides have largely replaced Al in part because the more refractory materials are less prone to diffuse into unintended areas especially during subsequent high-temperature processing.

After the metal contacts are made, the image sensors may be coupled to flat wires or metal ribbons and assembled into wired bonded packages. Image sensors may have a sheet of tempered glass on the illuminated side, and a polymer encapsulation on the other side. Tempered glass typically is incompatible for use with amorphous silicon devices because of the high temperatures during the deposition process. The adhesion between the glass and the image sensor is typically achieved by a layer of polymer adhesive. The presence of the polymer adhesive adjacent the glass and in front of the photosensitive components of the image sensor poses several disadvantages, including additional processing steps and cost, interference with the incident light (distortion, different transmittance range, etc.) before it reaches the photosensitive components, and structural issues (different CTE, thermal stability, photodegradation, etc.).

Thin-Film SOI Manufacture

Forming III-V semiconductor thin-film image sensors directly on a cover glass could be very advantageous in that it reduces the weight of the substrate and reduces integration process costs. An image sensor formed directly on glass practically could be configured to be backside illuminated, with incident light entering the cover glass substrate side. By comparison, researchers have investigated deposited polycrystalline thin films on glass substrates for space solar cell application. The crystal quality limits the performance of the III-V solar cells with polycrystalline films. Similarly, the low quantum efficiency of polycrystalline films make them undesirable for image sensors.

Creating a thin film structure, however, is not the end of the story. The resulting thin-film SOI structure of a thermal-bond exfoliation process just after exfoliation might exhibit excessive surface roughness (e.g., about 10 nm or greater), excessive silicon layer thickness (even though the layer is considered “thin”), unwanted hydrogen ions, and implantation damage to the silicon crystal layer (e.g., due to the formation of an amorphized silicon layer). Because one of the primary advantages of the SiOG material lies in the single-crystal nature of the film, this lattice damage must be healed or removed. Second, the hydrogen ions from the implant are not removed fully during the bonding process, and because the hydrogen atoms may be electrically active, they should be eliminated from the film to insure stable device operation. Lastly, the act of cleaving the silicon layer leaves a rough surface, which is known to cause poor transistor operation, so the surface roughness should be reduced to preferably less than 1 nm R_{A} prior to device fabrication.

These issues may be treated separately. For example, a thick (500 nm) silicon film is transferred initially to the glass. The top 420 nm then may be removed by polishing to restore the surface finish and eliminate the top damaged region of silicon. The remaining silicon film then may be annealed in a furnace for up to 8 hours at 600 degrees C. to diffuse out the residual hydrogen.

Chemical mechanical polishing (CMP) may be used also to process the SOI structure after the thin silicon film has been exfoliated from the silicon material wafer. Disadvantageously, however, the CMP process does not remove material uniformly across the surface of the thin silicon film during polishing. Typical surface non-uniformities (standard deviation/mean removal thickness) are in the 3-5% range for semiconductor films. As more of the silicon film's thickness is removed, the variation in the film thickness correspondingly worsens.

The above shortcoming of the CMP process is especially a problem for some silicon-on-glass applications because, in some cases, as much as about 300-400 nm of material needs to be removed to obtain a desired silicon film thickness. For example, in thin film transistor (TFT) fabrication processes, a silicon film thickness in the 100 nm range or less may be desired.

Another problem with the CMP process is that it exhibits particularly poor results when rectangular SOI structures (e.g., those having sharp corners) are polished. Indeed, the aforementioned surface non-uniformities are amplified at the corners of the SOI structure compared with those at the center thereof. Still further, when large SOI structures are contemplated (e.g., for photovoltaic applications), the resulting rectangular SOI structures are too large for typical CMP equipment (which are usually designed for the 300 mm standard wafer size). Cost is also an important consideration for commercial applications of SOI structures. The CMP process, however, is costly both in terms of time and money. The cost problem may be significantly exacerbated if non-conventional CMP machines are required to accommodate large SOI structure sizes.

In addition to CMP processing, a furnace anneal (FA) may be used to remove any residual hydrogen. However, high temperature anneals are not compatible with lower-cost glass or glass-ceramic substrates. Lower temperature anneals (less than 700 degrees C.) require long times to remove residual hydrogen, and are not efficient in repairing crystal damage caused by implantation. Furthermore, both CMP and furnace annealing increase the cost and lower the yield of manufacturing.

In contrast to microelectronic applications of SOI structures, image sensors are more tolerant of such defects, although such defects nonetheless adversely may affect performance of the image sensor. While such finishing techniques as CMP and FA may improve surface characteristics, the defect-tolerance of image sensor may make them cost-prohibitive.

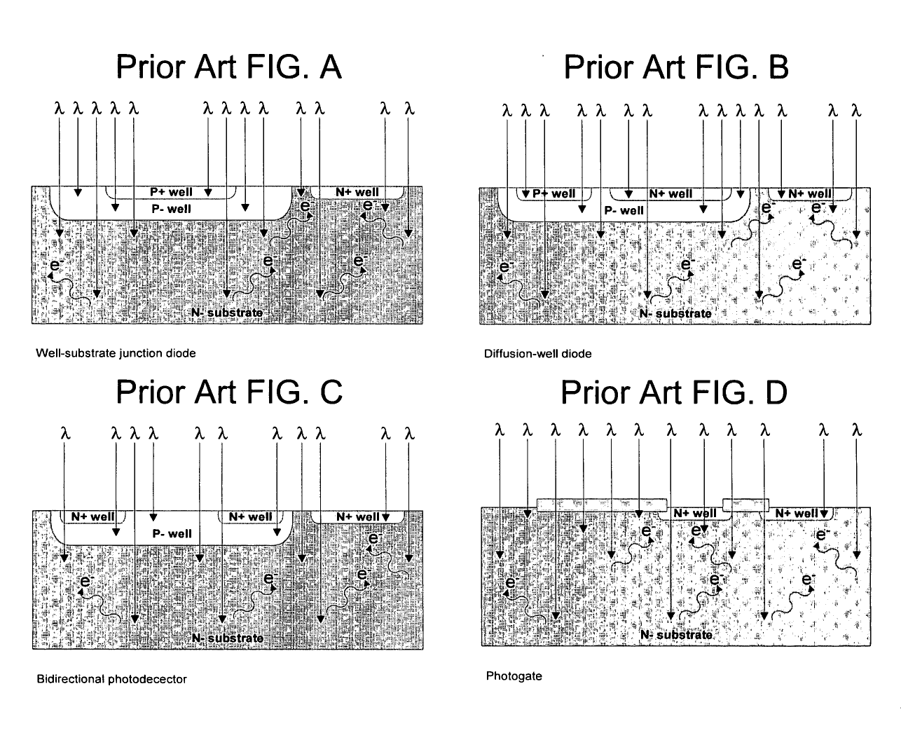

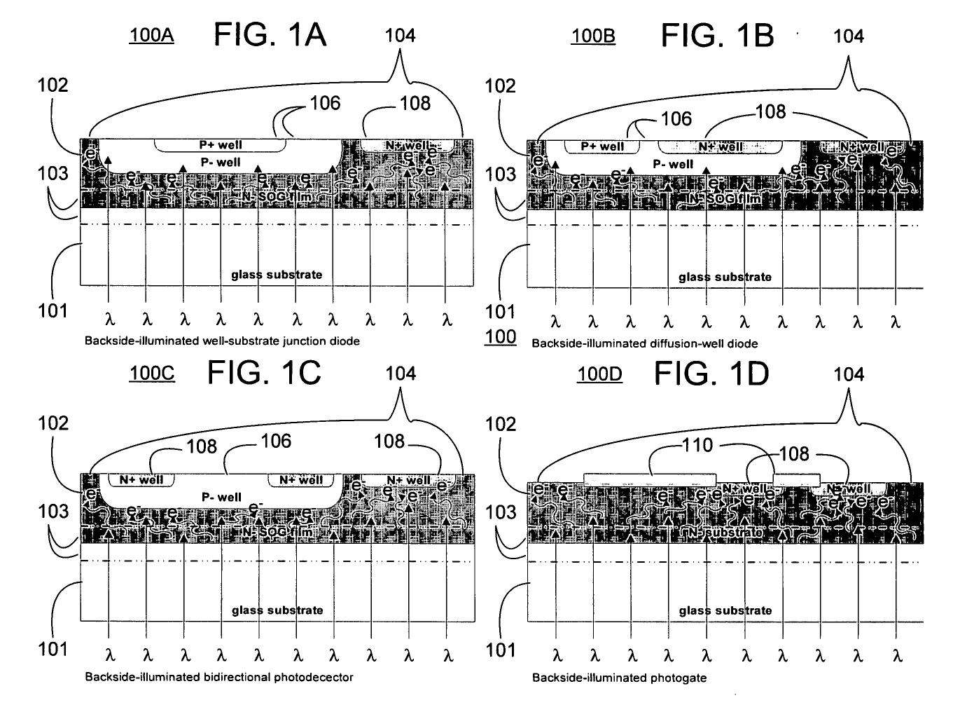

Referring to FIGS. 1A, 1B, 1C and 1D, occasionally referred to collectively as FIG. 1, there are shown image sensor variations 100A, 100B, 100C and 100D, respectively, of image sensor 100 in accordance with one or more embodiments of the present invention. The variations of image sensor 100 include backside-illuminated image sensor configurations, respectively, of a well-substrate junction diode, a diffusion-well diode, a bidirectional photodetector, and a photogate, each in accordance with one or more embodiments of the present invention. Although depicted as backside-illuminated, image sensors 100 could be configured to be front-side illuminated.

Broadly speaking, image sensor 100 may be referred to as an SOI structure. With respect to the figures, the SOI structure 100 is exemplified as an SiOG structure. The SiOG structure 100 may include an insulator substrate 101 made of glass, a semiconductor film 102, ion migration zones 103 (shown in more detail in FIG. 5B), and various image sensor features 104, such as one or more a p-type semiconductor regions 106, n-type semiconductor regions 108, and photogate regions 110. Additional image sensor features not shown but well known in the art include insulating regions, ohmic contact regions, gates, sources, drains, transistors, contact lines, etc. Use of the term “region” may mean a “layer” and vice-versa. The image sensor features generally will be proximate to the semiconductor film 102; that is to say, they may be in, on, underneath, adjacent, etc., the semiconductor film 102. The SiOG structure 100 has suitable uses in connection with image sensor devices, although the SOI structures of FIGS. 1A-1D are only partial representations of image sensor configurations and not intended to depict all image sensor features necessary for operation.

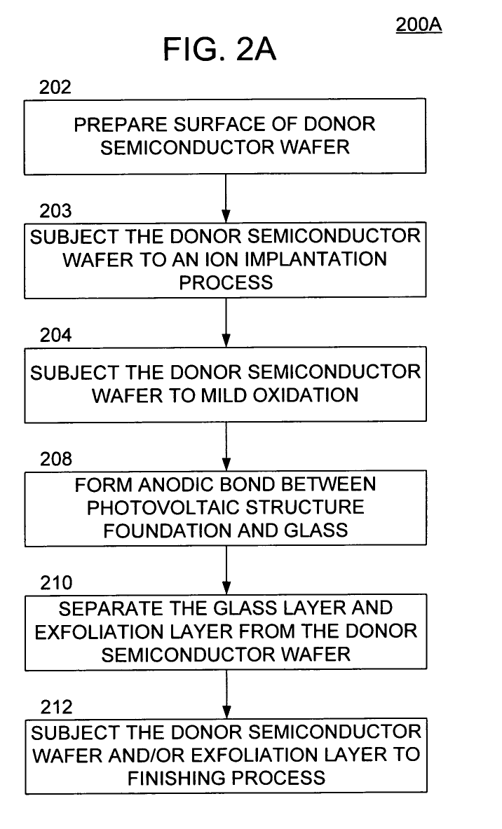

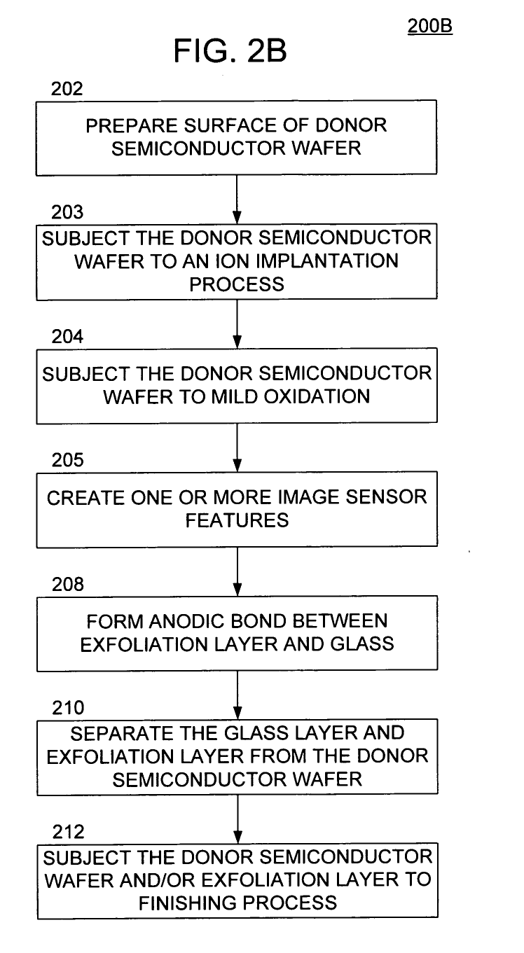

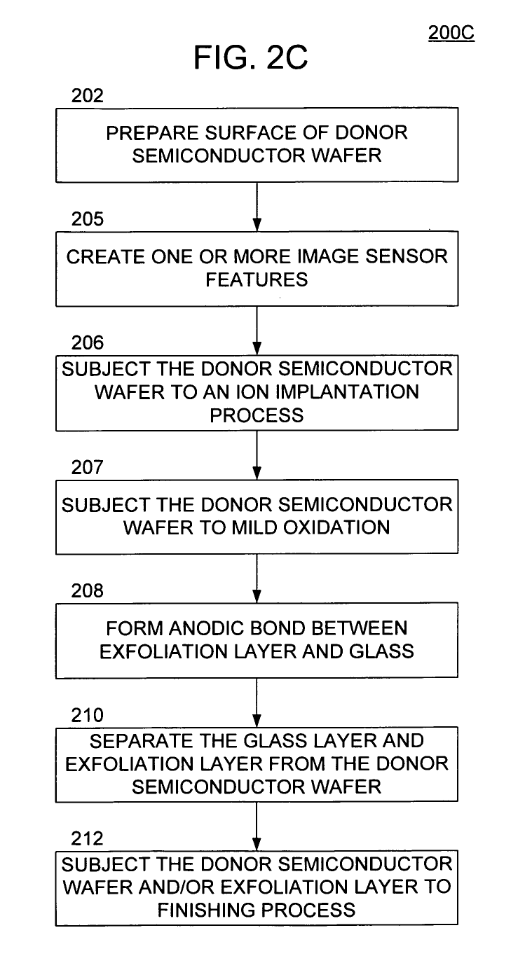

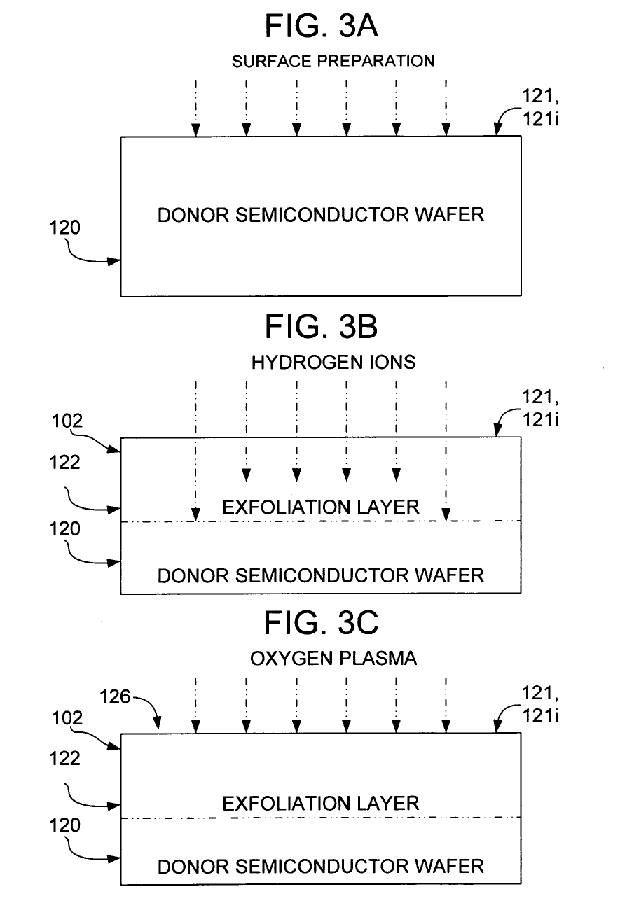

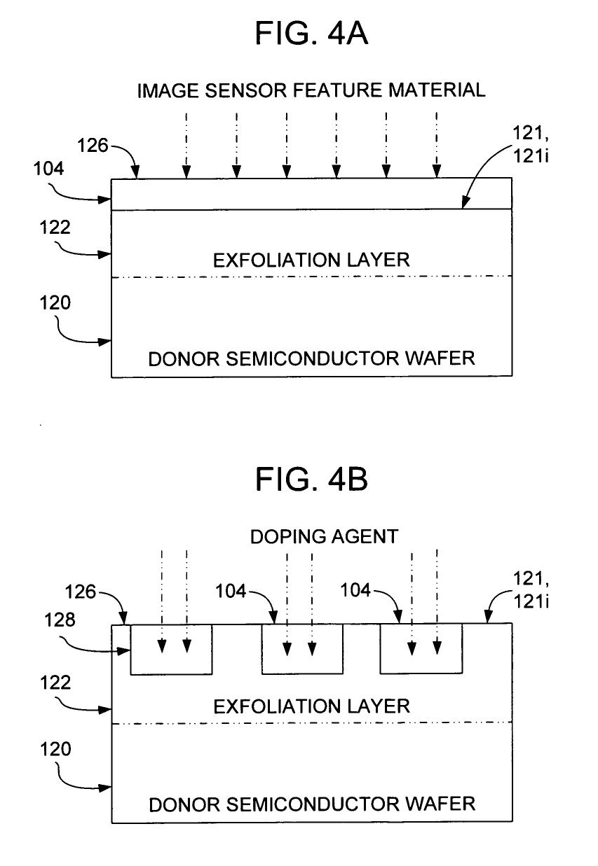

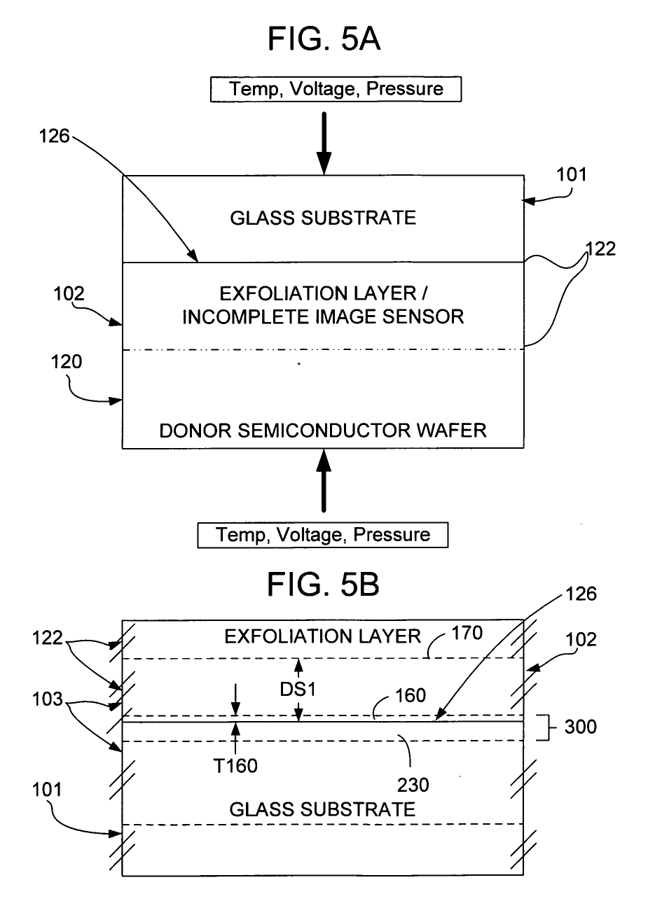

The semiconductor material of substrate 102 and regions 106 and 108 may be in the form of a substantially single-crystal material. Semiconductor film 102 preferably may comprise a substantially single crystal semiconductor layer, as it comes from donor wafer 120 introduced in FIGS. 2 and 3A. The term “substantially” is used in describing the layers 102, 106, and 108 to take account of the fact that semiconductor materials normally contain at least some internal or surface defects either inherently or purposely added, such as lattice defects or grain boundaries. The term substantially also reflects the fact that certain dopants may distort or otherwise affect the crystal structure of the semiconductor material. In particular, p-type semiconductor layer 106 includes a p-type doping agent, whereas n-type semiconductor layer 108 includes an n-type doping agent. Where it is desired that the majority of the electron hole pairs are created in the p-type layer 106, the p-type layer 106 generally will be thicker than the n-type layer 108.

For the purposes of discussion, it is assumed that the semiconductor layers 102, 106, 108 are formed from silicon, unless stated otherwise. It is understood, however, that the semiconductor material may be a silicon-based semiconductor or any other type of semiconductor, such as the III-V, II-IV, etc., classes of semiconductors. Examples of these materials include: silicon (Si), germanium-doped silicon (SiGe), silicon carbide (SiC), germanium (Ge), gallium arsenide (GaAs), gallium phosphide (GaP), and indium phosphide (InP).

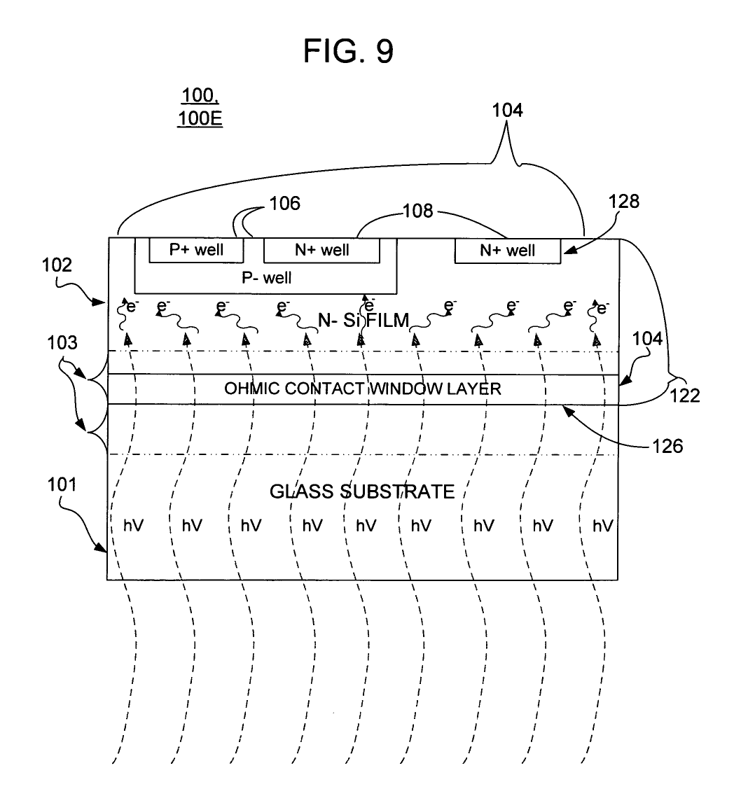

An ohmic contact region is a region on a semiconductor device that has been prepared so that the current-voltage (I-V) curve of the device is linear and symmetric. Depending on the placement and purpose, the ohmic contact regions may include conducting window layers. Similarly, depending on the placement and purpose, the ohmic contact regions may include back contact layers. An ohmic contact region may serve various purposes in image sensors, one of which is to provide bias. Backside-to-front-side bias can increase the quantum efficiency and signal-to-noise ratio for some image sensor configurations. Bias may be beneficial for front-side illumination as well. While the prior art includes several examples of backside conductive layers to provide back-to-front bias, the processes to accomplish those layers are cumbersome and costly and leave the imaging device in a fragile condition, unless affixed via adhesives to a support substrate. Overcoming issues associated with the prior art, a preferred embodiment of the present invention, as illustrated in FIG. 9, may include a conductive layer to provide bias and an improved method of incorporating the conductive layer into the image sensor.

A conducting window layer is a translucent and electrically conductive layer of material acting as an ohmic contact. For examples of a CCD with an ohmic window layer, refer to U.S. Pat. No. 6,259,085 B1 to Holland and U.S. Pat. No. 4,198,646 to Alexander et al. The conducting window layer may be transparent or semi-transparent. An exemplary material would be indium tin oxide, a material that typically is formed by reactive sputtering of an In—Sn target in an oxidative atmosphere. An alternative to indium tin oxide may include, for instance, aluminium-doped zinc oxide, boron-doped zinc oxide, or even carbon nanotubes. Indium tin oxide (ITO, or tin-doped indium oxide) is a mixture of indium (III) oxide (In₂O₃) and tin (IV) oxide (SnO₂), typically may be 90% In₂O₃, 10% SnO₂ by weight. It is transparent and colorless in thin layers. In bulk form, it is yellowish to grey. A main feature of indium tin oxide is the combination of electrical conductivity and optical transparency. However, a compromise has to be reached during film deposition, as high concentration of charge carriers will increase the material's conductivity, but decrease its transparency. Thin films of indium tin oxide are most commonly deposited on surfaces by electron beam evaporation, physical vapor deposition, or a range of sputtering techniques.

A back contact layer is a conductive layer, such as a conductive metal-based or metal oxide-based layer. For an example of a CCD made with an intermediate structure having an ohmic back contact layer, refer to U.S. Pat. No. 5,907,767 to Tohyama. The back contact material may be chosen for its thermal robustness in contact with Si. For instance, a back contact layer may be film based on aluminum or a silicide, such as or titanium disilicide, tungsten disilicide or nickel silicide, an example of which is discussed below. A silicide-polysilicon combination has better electrical properties than polysilicon alone and yet does not melt in subsequent processing.

The ohmic contact regions may be created, for example, by deposition, such as LPE, CVD or PECVD. Likewise, the ohmic contact regions may be formed by heavy doping of semiconductor film 102 after exfoliation separation, discussed with reference to step 210 of FIGS. 2 et seq. Mesotaxy or epitaxy may be used also. Whereas as epitaxy is the growth of a matching phase on the surface of a substrate, mesotaxy is the growth of a crystallographically matching phase underneath the surface of the host crystal. In this process, ions are implanted at a high enough energy and dose into a material to create a layer of a second phase, and the temperature is controlled so that the crystal structure of the target is not destroyed. The crystal orientation of the layer can be engineered to match that of the target, even though the exact crystal structure and lattice constant may be very different. For example, after the implantation of nickel ions into a silicon wafer, a layer of nickel silicide can be grown in which the crystal orientation of the silicide matches that of the silicon.

Use of doping to form regions 106 or 108, use of epitaxy or mesotaxy to form ohmic contact regions, and/or the use of various other methods to add, remove or change materials may be thought of as creating one or more image sensor features. If done prior to transfer of an exfoliation layer 122, introduced in FIGS. 2 and 3B, the process may create one or more image sensor features that then are transferred with the exfoliation layer.

Insofar as an image sensor feature, such as a conductive layer, is formed on or in the exfoliation layer 122, whether formed by epitaxy, mesotaxy, ion implantation, doping, vapor transport, vapor deposition, etc., the image sensor feature will be integral to the exfoliation layer 122. If the image sensor feature is formed on or in the exfoliation layer 122 before the exfoliation layer 122 is bonded to the insulator substrate 101, the image sensor feature will be proximate to the insulator substrate 101 when the exfoliation layer 122 is bonded to the substrate 101. In other words, the image sensor feature will have been formed near the side of the exfoliation layer 122 that faces the insulator substrate, such that, for example, the resulting image sensor feature may be between the insulator substrate and the exfoliation layer. If the exfoliation layer 122 is bonded to the insulator substrate 101 first and then the image sensor feature is formed on or in the exfoliation layer 122 thereafter, the image sensor feature will be on or near the side of the exfoliation layer 122 opposite the insulator substrate 101 and thus distal to the insulator substrate 101. Likewise, any image sensor feature regions formed in, on or above the exfoliation layer 122 after the exfoliation layer 122 has been bonded to the insulator substrate 101 will be distal to the insulator substrate 101.

As will be discussed in more detail in reference to FIG. 5, an ion migration zone 103 forms on either side of an anodic bond between the insulator substrate 101 and the layer bonded to the insulator substrate 101, which could be semiconductor film 102, in some cases, or other image sensor features, such as ohmic contact regions, in other cases. In the absence of pre-transfer image sensor features, semiconductor film 102 may bond directly to insulator substrate 101 when the exfoliation layer 122 is transferred to the insulator substrate 101. The ion migration zones 103 result from the anodic bonding process described in FIG. 5. These ion migration zones 103 have not been present in prior art image sensor structures.

The insulator substrate 101, exemplified here as a glass substrate 101, may be formed from an oxide glass or an oxide glass-ceramic. Although not required, the embodiments described herein may include an oxide glass or glass-ceramic exhibiting a strain point of less than about 1,000 degrees C. As is conventional in the glass making art, the strain point is the temperature at which the glass or glass-ceramic has a viscosity of 10^{14.6} poise (10^{13.6} Pa.s). As between oxide glasses and oxide glass-ceramics, the glasses may have the advantage of being simpler to manufacture, thus making them more widely available and less expensive.

By way of example, the glass substrate 101 may be formed from glass substrates containing alkaline-earth ions, such as, substrates made of CORNING INCORPORATED GLASS COMPOSITION NO. 1737 or CORNING INCORPORATED GLASS COMPOSITION NO. EAGLE²⁰⁰⁰ ™. These glass materials have other uses, in particular, for example, the production of liquid crystal displays.

Moreover, the insulator substrate 101 preferably should be matched to the imaging range of the image sensor and the accordingly selected semiconductor film 102. Inasmuch as a preferred embodiment uses a semiconductor film 102 made of silicon, which has an imaging range of around 400 to 1100 nanometers, the glasses to be used as substrates 101 thus should have very good transmittance in this range. The transmittance preferably should be over 90% in the imaging range, and most preferably over 95% over the desired wavelength range. One example of such a glass for a preferred embodiment using a silicon semiconductor film 102 is an alkaline earth alumino-borosilicate with the composition in weight percent of SiO2 57.7%, B2O3 8.4%, Al2O3 16.5%, MgO 0.75%, CaO 4.1%, SrO 1.9%, baO 9.4%. As will be appreciated by a person skilled in the art, there are many glasses and glass ceramic available with appropriate transmittance described in the literature which are useful for the purposes of this invention.

The glass substrate may have a thickness in the range of about 0.1 mm to about 10 mm, such as in the range of about 0.5 mm to about 3 mm. For some SOI structures, insulating layers having a thickness greater than or equal to about 1 micron (i.e., 0.001 mm or 1000 nm) are desirable, e.g., to avoid parasitic capacitive effects which arise when standard SOI structures having a silicon/silicon dioxide/silicon configuration are operated at high frequencies. In the past, such thicknesses have been difficult to achieve. In accordance with the present invention, an SOI structure having an insulating layer thicker than about 1 micron is readily achieved by simply using a glass substrate 101 having a thickness that is greater than or equal to about 1 micron. A lower limit on the thickness of the glass substrate 101 may be about 1 micron, i.e., 1000 nm.

In general, the glass substrate 101 should be thick enough to support the semiconductor film 102 through the bonding process steps, as well as subsequent processing performed on the SiOG structure 100. Although there is no theoretical upper limit on the thickness of the glass substrate 101, a thickness beyond that needed for the support function or that desired for the ultimate imaging SiOG structure 100 might not be advantageous since the greater the thickness of the glass substrate 101, the more difficult it will be to accomplish at least some of the process steps in forming the imaging SiOG structure 100.

The oxide glass or oxide glass-ceramic substrate 101 may be silica-based. Thus, the mole percent of SiO₂ in the oxide glass or oxide glass-ceramic may be greater than 30 mole percent and may be greater than 40 mole percent. In the case of glass-ceramics, the crystalline phase can be mullite, cordierite, anorthite, spinel, or other crystalline phases known in the art for glass-ceramics. Non-silica-based glasses and glass-ceramics may be used in the practice of one or more embodiments of the invention, but are generally less advantageous because of their higher cost and/or inferior performance characteristics.

Similarly, for some applications, e.g., for SOI structures employing semiconductor materials that are not silicon-based, glass substrates which are not oxide based, e.g., non-oxide glasses, may be desirable, but are generally not advantageous because of their higher cost. As will be discussed in more detail below, in one or more embodiments, the glass or glass-ceramic substrate 101 is designed to match a coefficient of thermal expansion (CTE) of one or more semiconductor materials (e.g., silicon, germanium, etc.) of the region(s) (potentially 102, 104, 106, 108, or 110) that is (are) bonded thereto, directly or indirectly. The CTE match ensures desirable mechanical properties during heating cycles of the deposition process.

For most imaging applications, the glass or glass-ceramic 101 may be transparent in the visible, near UV, and/or IR wavelength ranges, e.g., the glass or glass ceramic 101 may be transparent in the 350 nm to 2 micron wavelength range. Having transparent, or at least translucent, glass is important in particular in backside-illuminated image sensors 100A-D, where the light enters the insulator substrate 101 before reaching the rest of the structure of image sensor 100. However, in variations of image sensor 100 that are front-side illuminated, the light does not enter the insulator substrate 101, so it largely would be irrelevant whether the insulator substrate 101 is translucent, let alone transparent, in which case the insulator substrate 101 is chosen based on other criteria, inter alia CTE, not the least of which is cost.

Although the glass substrate 101 may be composed of a single glass or glass-ceramic layer, laminated structures m a y be used if desired. For instance, a light color filter may be laminated on the insulator substrate 101 for use in 3-CCD cameras. When laminated structures are used, the layer of the laminate closest to the layer bonded thereto (e.g., 102) may have the properties discussed herein for a glass substrate 101 composed of a single glass or glass-ceramic. Layers farther from the bonded layer may also have those properties, but may have relaxed properties because they do not directly interact with the bonded layer. In the latter case, the glass substrate 101 is considered to have ended when the properties specified for a glass substrate 101 are no longer satisfied.

Referring to FIGS. 2A, 2B and 2C, occasionally referred to collectively as FIG. 2, process steps are illustrated that may be carried out in order to produce the image sensor structure 100 in accordance with one or more embodiments of the present invention. Process 200A is depicted in FIG. 2A, process 200B is depicted in FIG. 2B, and process 200C is depicted in FIG. 2C. FIGS. 3-6 illustrate simplified intermediate and near-final structures that may be formed in carrying out the processes of FIGS. 2A, 2B and 2C.

At action 202 of FIGS. 2 and 3A, a prepared donor surface 121 of a donor semiconductor wafer 120 is prepared, such as by polishing, cleaning, etc. to produce a relatively flat and uniform prepared donor surface 121 suitable for bonding to a subsequent layer of the image sensor. The prepared donor surface 121 may form the underside, for example, of the semiconductor film 102. For the purposes of discussion, the semiconductor wafer 120 may be a doped (n-type or p-type) substantially single-crystal Si wafer, although as discussed above any other suitable semiconductor material may be employed.

At either action 203, for processes 200A and 200B, or action 206, for process 200C, also shown in FIG. 3B, an exfoliation layer 122 is created by subjecting an ion implantation surface 121i, i.e., the prepared donor surface 121, and any layer created on prepared donor surface 121, to one or more ion implantation processes to create a weakened region below the prepared donor surface 121 of the donor semiconductor wafer 120. Although the embodiments of the present invention are not limited to any particular method of forming the exfoliation layer 122, one suitable method dictates that the prepared donor surface 121 of the donor semiconductor wafer 120 may be subject to a hydrogen ion implantation process to at least initiate the creation of the exfoliation layer 122 in the donor semiconductor wafer 120.

The implantation energy may be adjusted using conventional techniques to achieve an approximate thickness of the exfoliation layer 122. By way of example, hydrogen ion implantation may be employed, although other ions or multiples thereof may be employed, such as boron + hydrogen, helium + hydrogen, or other ions known in the literature for exfoliation. Again, any other known or hereinafter developed technique suitable for forming the exfoliation layer 122 may be employed without departing from the spirit and scope of the present invention.

Depending on the parameters of the image sensor structure 100, the number and thickness of regions or layers on top of the prepared donor surface 121, and the potential use of any intermediate preparation step, such as CMP or FA, the exfoliation layer 122 may be made as thick or thin as desired and/or as feasible. If various design constraints require the exfoliation layer 122 to be thicker than desired, a known method of mass removal, such as CMP or polishing, may be used to reduce the thickness of the layer 122 after it is exfoliated in action 210. However, using a mass removal step adds time and expense to the overall manufacturing process and may not be necessary for image sensor 100. For instance, in variations 100A-D, the semiconductor film 102 may not need to be particularly thin or thick; preferably, semiconductor film 102 is thick enough to serve as a stable foundation for later finishing processes, but otherwise thin to conserve materials, and hence money.

The opposite issue may arise with image sensor 100, namely that the exfoliation layer 122 may be too thin. A thicker layer of Si may be desirable for a image sensor 100 because a thicker layer of Si will absorb more light. If the energy needed to create a desirably thick exfoliation layer 122 exceeds available equipment parameters, additional Si may be deposited or grown epitaxially after the exfoliation layer 122 is created. The additional Si may be added to the exfoliation layer 122 before or after it is transferred to the glass substrate 101. If added before the transfer, the Si addition becomes part of a pre-transfer creation of one or more image sensor features 104, whereas if added after, the Si addition becomes part of a post-transfer creation of one or more image sensor features 104. Whether before or after transfer, the one or more image sensor features 104 may be created using one or more of the finishing processes discussed in FIG. 7.

At either action 204, for processes 200A and 200B, or action 207, for process 200C, also shown in FIG. 3C, the ion implantation surface 121i, i.e., the prepared donor surface 121, and any layer created on prepared donor surface 121, on donor semiconductor wafer 120 may be treated to reduce, for example, the hydrogen ion concentration on the ion implantation surface 121i. For example, the donor semiconductor wafer 120 may be washed and cleaned, and the bonding surface 126 of the exfoliation layer 122 may be subjected to mild oxidation. Broadly speaking, the washing, cleaning, and oxidating may be thought of as finishing processes. The mild oxidation treatments may include treatment in oxygen plasma, ozone treatments, treatment with hydrogen peroxide, hydrogen peroxide and ammonia, hydrogen peroxide and an acid or a combination of these processes. It is expected that during these treatments hydrogen-terminated surface groups oxidize to hydroxyl groups, which in turn also makes the surface of the bonding surface 126 hydrophilic. The treatment may be carried out at room temperature for the oxygen plasma and at temperature between 25-150° C. for the ammonia or acid treatments.

Action 205 of FIGS. 2B and 2C, also shown in FIGS. 4A and 4B, involves creating one or more image sensor features 104 on the donor semiconductor wafer 120. The image sensor features 104 may be created either after the exfoliation layer 122, as in process 200B, or before the exfoliation layer 122, as in process 200C. After both the exfoliation layer 122 and the image sensor features 104 are created, though, reference to the exfoliation layer 122 encompasses them both as they form an integral unit. An exposed surface of the image sensor features 104 will be a bonding surface 126 for bonding to the glass insulator substrate 101 in action 208.

With reference to FIGS. 4A and 4B, occasionally referred to collectively as FIG. 4, the donor semiconductor wafer 120 may be processed as part of the creation of an one or more pre-transfer image sensor features 104. Creation of one or more pre-transfer image sensor features 104 results in the formation in the exfoliation layer 122 of a structure that may be thought of as an incomplete image sensor. An incomplete image sensor would include at least the semiconductor film 102 and one or more image sensor features 104. FIG. 4 depicts the exfoliation layer 122 as already having been formed on the prepared donor surface 121 of the donor semiconductor wafer 120, when further steps are taken in the creation of one or more pre-transfer image sensor features 104. Many different actions may be taken in creating one or more pre-transfer image sensor features 104. For instance, creation of the image sensor features 104 may include, as shown in FIG. 4A, addition of material, such as metal, for the formation of ohmic contact regions, or as shown in FIG. 4B, use of an intermediary doping step to create p-type or n-type semiconductor regions 106 or 108.

FIG. 4A depicts the addition, according to one or more embodiments of the present invention, of material to form an image sensor feature, such as either a back contact layer or a conducting window layer. On a high level, the process specific to a particular material is irrelevant, and so all processes may be depicted using one block diagram. What is relevant is that material may be added before the exfoliation layer 122 is transferred. While a simplified deposition process is depicted, such as CVD or PECVD, the diagram is meant to represent any possible process, such as epitaxy and mesotaxy, as discussed above. Where one or more layers are desired between the semiconductor film 102 and the insulator substrate 101, it is preferred that the layer(s) be deposited on the exfoliation layer 122, rather than directly on the glass substrate 101, prior to bonding the exfoliation layer 122 and the glass substrate 101, insofar as the anodic bonding process of action 208 appears to work better in this sequence. Another benefit of depositing one of the layer(s) onto the exfoliation layer 122 while attached to the donor semiconductor wafer 120 would be the relaxation of process constraints required to deposit the layer(s) directly onto the glass substrate 101, which may be more sensitive to extreme conditions.

FIG. 4B depicts the ion implantation surface 121i of exfoliation layer 122 being doped, creating a subsurface n-p junction 128. Depending on configuration is desired, for example, semiconductor regions 106, 108 may be made from a doped Si boule that receives an opposite doping on its surface. In an exemplary embodiment of variation 100B, an n-type doped donor semiconductor wafer 120 may be doped on its surface with a p-type doping agent, creating a subsurface n-p junction in regions 106. Furthermore, the larger region 106 in 100B and the adjacent film 102 may then be doped further with n-type doping agent to create n+ well regions 108. Conversely, a p-type doped donor semiconductor wafer 120 may be doped on its surface with an n-type doping agent, likewise creating a subsurface n-p junction.

At action 208, in FIGS. 2 and 5A, the glass substrate 101 may be bonded to the bonding surface 126 of the exfoliation layer 122. A suitable bonding and separating process is described in U.S. Patent Application Publication No. 2004/0229444, the entire disclosure of which is hereby incorporated by reference, which discloses a process that produces an SOI structure.

According to one or more embodiments of Publication 2004/0229444, the steps include: (i) exposing a silicon wafer surface to hydrogen ion implantation to create a separation zone; (ii) bringing the wafer surface into contact with a glass substrate; (iii) applying pressure, temperature and voltage to the wafer and the glass substrate to facilitate bonding therebetween; and (iv) cooling the structure to a common temperature to facilitate separation of the glass substrate and a thin layer of silicon from the silicon wafer.

More generally speaking, in view of the related art, a donor substrate and a recipient substrate are provided, wherein the donor substrate comprises a semiconductor material (e.g., Si, Ge, GaAs, etc.) and the recipient substrate comprises an insulator material (e.g., oxide glass or oxide glass-ceramic). The donor substrate includes a first donor external surface and a second donor external surface, the first donor external surface opposing the second donor external surface and comprising a first bonding surface for bonding with the recipient substrate. The recipient substrate includes a first recipient external surface and a second recipient external surface, the first recipient external surface opposing the second recipient external surface and comprising a second bonding surface for bonding to the donor substrate.

A plurality of ions are implanted through the first donor external surface to create an ion implantation zone of the donor substrate at an implantation depth below the first donor external surface, after which the first and second bonding surfaces are brought into contact. For a period of time sufficient for the donor and recipient substrates to bond to one another at the first and second bonding surfaces, simultaneously: (1) forces are applied to the donor substrate and/or the recipient substrate such that the first and second bonding surfaces are pressed into contact; (2) the donor and recipient substrates are subjected to an electric field being generally directed from the second recipient external surface to the second donor external surface; and (3) the donor and recipient substrates are heated differentially, so that the second donor external surface and the second recipient external surface have average temperatures T1 and T2, respectively.

Temperatures T1 and T2 are selected such that upon cooling to a common temperature, the donor and recipient substrates undergo differential contraction to thereby weaken the donor substrate at the ion implantation zone. Thereafter, the bonded donor and recipient substrates are cooled, splitting the donor substrate at the ion implantation zone. The insulator material preferably is chosen to comprise positive ions that move during bonding within the recipient substrate in a direction away from the second bonding surface and towards the second recipient external surface.

Portions of the Publication 2004/0229444 process, known by various names, such as anodic bonding, electrolysis, bonding by means of electrolysis, and forming an anodic bond by electrolysis, are discussed below in reference to the present invention. For purposes of the present invention, these names are used interchangeably. In the anodic bonding/electrolysis process, appropriate surface cleaning of the glass substrate 101 (and the bonding surface 126 of exfoliation layer 122 if not done already) may be carried out. Thereafter, the intermediate structures are brought into direct or indirect contact to achieve the arrangement schematically illustrated in FIG. 5.

Prior to or after the contact, the structure(s) comprising the donor semiconductor wafer 120, the exfoliation layer 122 and the glass substrate 101 are heated under a differential temperature gradient. The glass substrate 101 may be heated to a higher temperature than the donor semiconductor wafer 120 and exfoliation layer 122. By way of example, the temperature difference between the glass substrate 101 and the donor semiconductor wafer 120 (and the exfoliation later 122/incomplete image sensor) is at least 1 degree C., although the difference may be as high as about 100 to about 150 degrees C. This temperature differential is desirable for a glass having a coefficient of thermal expansion (CTE) matched to that of the donor semiconductor wafer 120 (such as matched to the CTE of silicon) since it facilitates later separation of the exfoliation layer 122 from the semiconductor wafer 120 due to thermal stresses. The glass substrate 101 and the donor semiconductor wafer 120 may be taken to a temperature within about 150 degrees C. of the strain point of the glass substrate 101.

Once the temperature differential between the glass substrate 101 and the donor semiconductor wafer 120 is stabilized, mechanical pressure is applied to the intermediate assembly. The pressure range may be between about 1 to about 50 psi. Application of higher pressures, e.g., pressures above 100 psi, might cause breakage of the glass substrate 101. The appropriate pressure may be determined in light of the manufacturing parameters, such as materials being used, and their thicknesses.

Next, a voltage is applied across the intermediate assembly, for example with the donor semiconductor wafer 120 at the positive electrode and the glass substrate 101 the negative electrode. The application of the voltage potential causes alkali or alkaline earth ions in the glass substrate 101 to move away from the semiconductor/glass interface further into the glass substrate 101. This accomplishes two functions: (i) an alkali or alkaline earth ion free interface is created; and (ii) the glass substrate 101 becomes very reactive and bonds strongly to the exfoliation layer 122 of the donor semiconductor wafer 120.

At action 210, of FIGS. 2 and 5A, after the intermediate assembly is held under the above conditions for some time (e.g., approximately 1 hour or less), the voltage is removed and the intermediate assembly is allowed to cool to room temperature. The donor semiconductor wafer 120 and the glass substrate 101 are then separated, which may include some peeling if they have not already become completely free, to obtain a glass substrate 101 bonded to the relatively thin exfoliation layer 122 formed of the semiconductor material of the donor semiconductor layer 120. The separation may be accomplished via fracture at the ion implantation zone due to thermal stresses. Alternatively or in addition, mechanical stresses, such as water jet or laser cutting, or chemical etching may be used to facilitate the separation.

Referring to FIG. 5B, the ion migration zone 103 mentioned in reference to FIG. 1 is shown in greater detail. The structural details pertain particularly to the anodic bond region at the interface of the glass substrate 101 and the layer just above it, the exfoliation layer 122. The bonding process (action 208) transforms the interface between the exfoliation layer 122 and the glass substrate 101 into an interface region 300. The interface region 300 preferably comprises a hybrid region 160 and a depletion region 230. The interface region 300 may also include one or more positive ion pile-up regions in the vicinity of the distal edge of the depletion region 230.

The hybrid region 160 is of enhanced oxygen concentration having thickness T160. If an image sensor feature layer exists at the bonding surface 126, such as a conducting window layer, for instance, this hybrid region 160 may be enhanced by beginning with a conducting window composition stoichiometrically depleted of oxygen to enhance oxygen transfer from the glass substrate 101. This thickness T160 may be defined in terms of a reference concentration for oxygen at a reference surface 170 within the exfoliation layer 122. The reference surface 170 is substantially parallel to the bonding surface 126 between the glass substrate 101 and the exfoliation layer 122 and is separated from that surface by a distance DS1. Using the reference surface 170, the thickness T160 of the hybrid region 160 will typically satisfy the relationship:

T160≦200 nm,

where T160 is the distance between bonding surface 126 and a surface which is: (i) substantially parallel to bonding surface 126, and (ii) is the surface farthest from bonding surface 126 for which the following relationship is satisfied:

CO(x)—CO/Ref≧50 percent,0≦x≦T160,

where CO(x) is the concentration of oxygen as a function of distance x from the bonding surface 126, CO/Ref is the concentration of oxygen at the above reference surface 170, and CO(x) and CO/Ref are in atomic percent.

Typically, T160 will be substantially smaller than 200 nanometers, e.g., on the order of about 50 to about 100 nanometers. It should be noted that CO/Ref will typically be zero, so that the above relationship will in most cases reduce to:

CO(x)≧50 percent,0≦x≦T160.

In connection with the depletion region 230, the oxide glass or oxide glass-ceramic substrate 101 preferably comprises at least some positive ions that move in the direction of the applied electric field, i.e., away from the bonding surface 126 and into the glass substrate 101. Alkali ions, e.g., Li⁺¹, Na⁺¹, and/or K⁺¹ ions, are suitable positive ions for this purpose because they generally have higher mobility rates than other types of positive ions typically incorporated in oxide glasses and oxide glass-ceramics, e.g., alkaline-earth ions.

However, oxide glasses and oxide glass-ceramics having positive ions other than alkali ions, e.g., oxide glasses and oxide glass-ceramics having only alkaline-earth ions, can be used in the practice of the invention. The concentration of the alkali and alkaline-earth ions can vary over a wide range, representative concentrations being between 0.1 and 40 weight percent on an oxide basis. Preferred alkali and alkaline-earth ion concentrations are 0.1 to 10 weight percent on an oxide basis in the case of alkali ions, and 0-25 weight percent on an oxide basis in the case of alkaline-earth ions.

The electric field applied in the bonding step (action 208) moves the positive ions (cations) further into the glass substrate 101 forming the depletion region 230. The formation of the depletion region 230 is especially desirable when the oxide glass or oxide glass-ceramic contains alkali ions, since such ions are known to interfere with the operation of semiconductor devices. Alkaline-earth ions, e.g., Mg⁺², Ca⁺², Sr⁺², and/or Ba⁺², can also interfere with the operation of semiconductor devices and thus the depletion region also preferably has reduced concentrations of these ions.

It has been found that the depletion region 230 once formed is stable over time even if the image sensor 100 is heated to an elevated temperature comparable to, or even to some extent higher than, that used in the bonding process. Having been formed at an elevated temperature, the depletion region 230 is especially stable at the normal operating and formation temperatures of image sensors. These considerations ensure that alkali and alkaline-earth ions will not diffuse back from the oxide glass or oxide glass-ceramic 101 into the semiconductor material 102 during use or further device processing, which is an important benefit derived from using an electric field as part of the bonding process.

As with selecting the operating parameters to achieve a strong bond, the operating parameters needed to achieve a depletion region 230 of a desired width and a desired reduced positive ion concentration for all of the positive ions of concern can be readily determined by persons skilled in the art from the present disclosure. When present, the depletion region 230 is a characteristic feature of an image sensor 100 produced in accordance with one or more embodiments of the present invention.

As illustrated in FIG. 6, after separation, the resulting structure may include the glass substrate 101 and the exfoliation layer 122 of semiconductor material bonded thereto. The cleaved surface 123 of the SOI structure just after exfoliation may exhibit excessive surface roughness 123A (depicted abstractly in FIG. 6), possible excessive silicon layer thickness (unlikely for imaging applications), and implantation damage of the silicon layer (e.g., due to hydrogen ions and the formation of an amorphized silicon layer).

At action 212, in FIGS. 2 and 7, the donor semiconductor wafer 120 and/or exfoliation layer 122, e.g., semiconductor film 102, may be subjected to one or more finishing process(es) 130. Inasmuch as most finishing processes 130 likely would occur after transfer of the exfoliation layer 122, some finishing processes 130 may occur before bonding, action 208. For instance, actions 204/207 and 205 may be considered finishing processes 130. Each finishing process 130 may include, for example, one or more subprocesses. For instance, a finishing process 130 may include various scribing steps needed to create the topography of various image sensor configurations. Such scribing steps, well known in the art, may be done before, after, or in conjunction with other finishing processes 130. Other finishing processes might include adding insulating, encapsulating or passivating regions at various locations. More generally, whatever process is needed to complete the incomplete image sensor may be considered a finishing process.

Another finishing process 130 may include augmenting the semiconductor thickness of the exfoliation layer 122. For instance, epitaxially growing more an additional semiconductor layer 132 may be less expensive than exfoliating a thicker layer. Exfoliating a thin layer 122 conserves the donor wafer 120 and reduces the energy required for deeper ion implantation needed to achieve a thicker exfoliation layer 122. Semiconductor material might be added, for example, before mesotaxial growth of a back contact layer. It is desired in certain embodiments that the final combined thickness of the semiconductor layers 102, 106 and 108 preferably should be, for example, more than 10 microns (i.e., 10000 nm) and less than about 30 microns. Therefore, an appropriately thick exfoliation layer 122 should be created and augmented with an additional semiconductor layer 132 (e.g., of Si) until the desired thickness is created. Augmentation with an additional Si layer 132 may include a doping step as well.

Historically, the amorphized silicon layer has been on the order of about 50-150 nm in thickness, and depending on the implantation energy and implantation time, the thickness of the exfoliation layer 122 has been on the order of about 500 nm. As with microelectronic SOI structures, however, a thinner exfoliation layer 122 may be created for the semiconductor film 102, with the amorphized silicon layer necessarily being thinner as well, with more semiconductor material added in the finishing processes, as discussed above.

Also according to action 212, the cleaved surface 123 may subject to post-cleaving processing which may include subjecting the cleaved surface 123 to a polishing or annealing process to reduce roughness 123A. Moreover, the finishing process may include application of a conducting window layer, such as deposition of indium tin oxide. Conversely, the finishing process may include application of a back contact region, such as a conductive metal-based or metal oxide-based region, such as an aluminum-based film deposited by LPE, CVD or PECVD. As discussed above, a back contact layer also may be formed by epitaxial or mesotaxial growth, such as of nickel silicide.

To the extent that finishing processes are used prior to exfoliation to create an incomplete image sensor, the incomplete image sensor has more of the features of the intended final product, so fewer finishing processes are necessary after exfoliation. By contrast, insofar as the formation of semiconductor film 102 on insulator substrate 101 alone, apart from the image sensor context, does not distinguish the substrate 101-film 102 combination as an image sensor over any other semiconductor-on-insulator structure, one or more image sensor-specific finishing processes may be necessary. However, having a substantially single crystal layer as the semiconductor film 102 relaxes the parameters within which to operate and expands the scope of options and outcomes available from which to choose, in proceeding with the finishing processes.

In particular, formation of the film 102, with or without other image sensor features 104, allows for greater flexibility in the creation of advanced, multi-junction imaging devices. For example, building on a film 102 of crystal-Si, a manufacturer may exploit the different specific heat capacities of crystal-Si versus GaAs, Ge, and GaInP₂ to create various multi-junction layers of GaAs, Ge and GaInP₂ to create new image sensors building on the advances in photovoltaic cell technology. Optionally, as the preferred embodiments of FIG. 9 describe, the film 102 may comprise Ge, or GaAs, or a doped Ge/GaAs layer.

Alternative embodiments of the invention will now be described with reference to the aforementioned SiOG processes and further details. For example, a result of separating the exfoliation layer 122 from the donor semiconductor wafer 120 may produce a first cleaved surface of the donor semiconductor wafer 120 and a second cleaved surface 123 of the exfoliation layer 122. As previously discussed, the finishing process 130 may be applied to the second cleaved surface 123 of the exfoliation layer 122. Additionally or alternatively, the finishing process 130 may be applied to the first cleaved surface of the donor semiconductor wafer 120 (using one or more of the techniques described above), such as polishing.

In another embodiment of the present invention, the donor semiconductor wafer 120 may be part of a donor structure, including a substantially single-crystal donor semiconductor wafer 120, and an epitaxial semiconductor layer disposed on the donor semiconductor wafer 120. (Details of an epitaxially grown semiconductor layer in an SOI context may be found in co-pending U.S. patent application Ser. No.: 11/159,889, filed Jun. 23, 2005, the entire disclosure of which is incorporated herein by reference.) The exfoliation layer 122, therefore, may be formed substantially from the epitaxial semiconductor layer (and may also include some of the single-crystal donor semiconductor material from the wafer 120). Thus, the aforementioned finishing process may be applied to the cleaved surface 123 of an exfoliation layer 122 formed substantially of epitaxial semiconductor material and/or a combination of epitaxial semiconductor material and single-crystal semiconductor material.

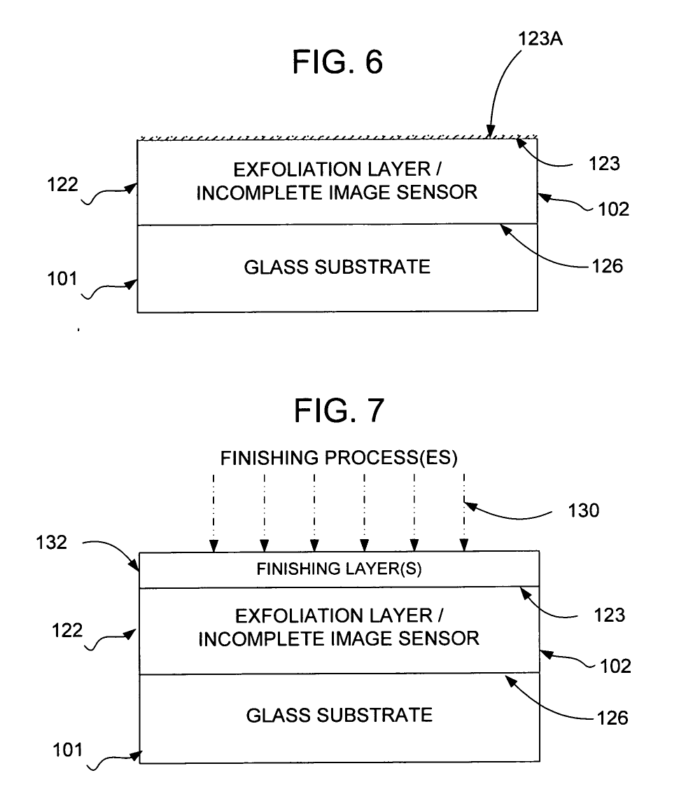

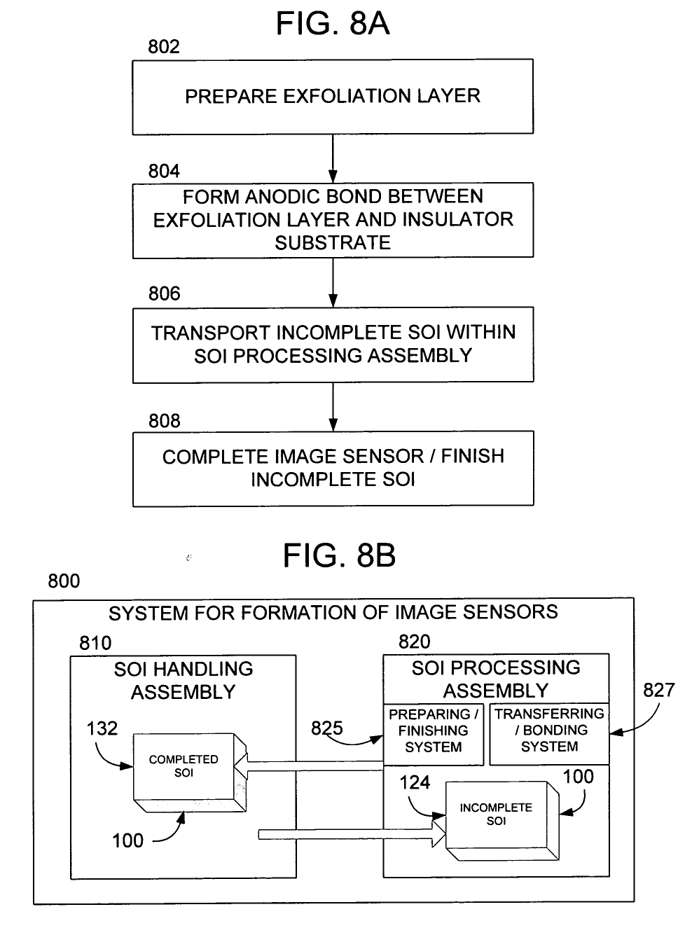

As depicted in FIG. 8A, showing exemplary formation steps 802-808, and FIG. 8B, showing an exemplary system 800, the image sensor creation process could be automated, moreover, in a system 800 for the formation of image sensors 100. The system 800 could include an image sensor handling assembly 810 (or SOI handling assembly 810, more generally), which handles the image sensors 100 for processing, and an image sensor/SOI processing assembly 820. The SOI processing assembly 820 would include various subsystems, such as a preparing or finishing system 825 and a transferring or bonding system 827, used in manufacturing image sensors 100 being handled by the semiconductor-on-insulator handling assembly 810. Until an image sensor is completed, it may be referred to as an intermediate structure.

For example, when the exfoliation layer 122 is prepared (step 802), the handling assembly 810 could transport and position the image sensor 100 in need of completion within the SOI processing assembly 820 to permit anodic bonding (step 804) to occur. Further transportation and positioning (step 806) of the substrate 101, bonded to exfoliation layers 122, within the SOI processing assembly 820 may allow additional actions 210 and 212 of exfoliating and finishing, respectively, to occur (step 808).

Referring to FIG. 9, a simplified image sensor 100 of variation 100E according to one or more preferred embodiments of the present invention is depicted. In accordance with one or more preferred embodiments, an optional ohmic contact window layer, acting as a backside transparent electrode for backside to front-side bias, is first applied to an n-type silicon donor wafer, wherein the silicon wafer is first coated with doped polysilicon, which is used as an electrode. In order to illustrate the advantage of bias, FIG. 9 shows most of the incident light rays terminating in the N—Si film layer & generating electrons there, similar to FIG. 1. The n-type silicon donor wafer may be implanted with hydrogen at an implantation energy from 1 Kev to 1000 Kev. The implantation depth range related to this energy range is from 0.02 to 17 microns. The desired silicon thickness is thus obtained by adjusting the implantation energy. The implantation dosage may be from 1.10¹⁶ to 10.10¹⁶ ions/cm². The wafer then may be cleaned by chemical means and subjected to oxygen plasma treatment to oxidize the surface groups. An alkali-alumino-borosilicate glass wafer with thermal expansion matched to silicon and thickness of 0.6-0.7 mm then may be washed with standard cleaning techniques, such as with a detergent and distilled water followed by a dilute acid wash to clean the surface. The glass and silicon are then heated, with the glass being at a temperature about 100 C higher than that of the silicon. The temperatures of the glass and silicon wafer, respectively, may be about 350 C and 450 C below the strain point temperature of the glass. The two wafers then may be brought into contact, with the thin polySi layer to the glass, and placed in a bonding system. A voltage of 1000V may be applied across the wafers with the application of 5-10 psi of pressure for 10 minutes before cooling down and removing the applied voltage. The applied voltage is a function of glass or glass-ceramic composition which determines the conductivity of the glass wafer.

A thin film of silicon bonded to the glass may be separated from the mother wafer, with very strong bonding to the glass being achieved. The SOG wafer is then subjected to the finishing processes 130 to fabricate a CCD or CMOS structure. For example, the glass wafer 101 with the Si film 102 then may be polished, annealed or healed to remove the damaged silicon top layer and reveal a good quality layer surface. Depending on the structure desired, process steps may include doping with phosphorous or boron ions, epitaxial growth of Si or GaAs, deposition of gate electrode material, and various photolithographic etchings.

This wafer may be used as a substrate to grow epitaxial structures, to form the image sensor. Examples of materials may include GaAs, GaInP/GaAs, GaₓIn_{y}P/Ga_{c}, In_{d}As/Ge and others known in the art. Various processes may be utilized to deposit the epitaxial films including CVST (closed space vapor transport), MOCVD (metalo-organic chemical vapor deposition), MBE (molecular beam epitaxy) and others known in the art. A number of surface passivating window layers such as wide bandgap epilayers of AlGaAs, InGaP or ZnSe may be employed as well as other encapsulating or passivation layers and surface treatments may be used to complete the sensor. Likewise, the ohmic contacts may be applied in varying configurations, depending on the device design.

The additional design parameters made available by using such an SOG structure 100 for imaging devices—including varying the thickness of the bonded semiconductor film 102 and the freedom to manipulate front-side structure without blocking backside illumination—can be used for advantage of optimizing the quantum efficiency of the device and/or reducing manufacturing complexity and costs. These benefits might be gained even for front-side illuminated device designs. Perhaps the greater design flexibility will enable some new imaging device designs and/or fabricated structures that were previously impractical or impossible.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

We claim:

1. A method of forming an image sensor, the method comprising:
creating an exfoliation layer of a donor semiconductor wafer, wherein the creating the exfoliation layer comprises subjecting the donor semiconductor wafer to an ion implantation process;
forming an anodic bond between the exfoliation layer and an insulator substrate;
separating the exfoliation layer from the donor semiconductor wafer, thereby exposing an at least one cleaved surface; and
creating a plurality of image sensor features proximate to the exfoliation layer.

2. The method of claim 1, further comprising: subjecting the exfoliation layer and/or donor semiconductor wafer to at least one finishing process.

3. The method of claim 2, wherein the exfoliation layer is subjected to the at least one finishing process before bonding.

4. The method of claim 2, wherein the donor semiconductor wafer is subjected to the at least one finishing process before the ion implantation process.

5. The method of claim 4, wherein subjecting the donor semiconductor wafer to the at least one finishing process creates at least one image sensor feature.

6. The method of claim 2, wherein the donor semiconductor wafer is subjected to the at least one finishing process after the ion implantation process but before forming an anodic bond.

7. The method of claim 6, wherein subjecting the donor semiconductor wafer to the at least one finishing process creates at least one image sensor feature.

8. The method of claim 2, wherein the at least one cleaved surface is subjected to the at least one finishing process.

9. The method of claim 8, wherein the at least one cleaved surface includes a first cleaved surface of the donor semiconductor wafer and a second cleaved surface of the exfoliation layer.

10. The method of claim 9, wherein the at least one finishing process is applied to at least the second cleaved surface of the exfoliation layer.

11. The method of claim 9, wherein the at least one finishing process is applied to at least the first cleaved surface of the donor semiconductor wafer.

12. The method of claim 2, wherein the at least one finishing process includes at least one process selected from a group including scribing, polishing, annealing, cleaning, doping, creating an ohmic contact, creating a gate, creating circuitry, creating a passivating region, creating an encapsulating region, and adding additional semiconductor material.

13. The method of claim 2, wherein the plurality of image sensor features includes a conductive region.

14. The method of claim 13, wherein the conductive region comprises a metal-based material or a metal-oxide based material.

15. The method of claim 13, wherein the conductive region includes one or more of a back contact region and a conducting window region, wherein:
the back contact region comprises aluminum, titanium, nickel, tungsten, indium, molybdenum, gold, platinum, palladium, gallium, tin, antimony, silver, germanium, or a silicide; and
the conducting window region comprises tin-doped indium oxide, aluminum-doped zinc oxide, boron-doped zinc oxide, or carbon nanotubes.

16. The method of claim 1, wherein forming an anodic bond by means of electrolysis includes:
heating at least one of the insulator substrate and the donor semiconductor wafer;
bringing the insulator substrate into direct or indirect contact with the exfoliation layer of the donor semiconductor wafer; and
pressing together the insulator substrate and the exfoliation layer; and
applying a voltage potential across the insulator substrate and the donor semiconductor wafer to induce the anodic bond.

17. The method of claim 1, wherein the donor semiconductor wafer comprises a substantially single-crystal donor semiconductor wafer comprising silicon, germanium, or gallium-arsenide.

18. The method of claim 1, wherein the donor semiconductor wafer material is taken from the group consisting of: silicon (Si), germanium-doped silicon (SiGe), silicon carbide (SiC), germanium (Ge), gallium arsenide (GaAs), gallium phosphide (GaP), and indium phosphide (InP).

19. The method of claim 1, wherein the donor semiconductor wafer includes a substantially single-crystal donor semiconductor wafer, and the separated exfoliation layer is formed substantially from the single-crystal donor semiconductor wafer material.

20. The method of claim 1, wherein the donor semiconductor wafer includes a donor semiconductor wafer and an epitaxial semiconductor layer disposed on the donor semiconductor wafer, and the separated exfoliation layer is formed substantially from the epitaxial semiconductor layer.

21. The method of claim 1, wherein creating the plurality of image sensor features involves one or more of epitaxy, mesotaxy, exfoliation, doping, vapor transport, vapor deposition, ion implantation, and oxidation.

22. The method of claim 1, wherein the exfoliation layer comprises an n-type semiconductor layer, a p-type semiconductor layer, or a semiconductor junction layer having n-type and p-type doped regions.

23. The method of claim 1, wherein creating the plurality of image sensor features comprises epitaxially growing a crystalline semiconductor region.

24. The method of claim 1, wherein the plurality of image sensor features includes at least one n-type doped region, at least one p-type doped region, at least one conductive region, at least one gate, and circuitry.

25. The method of claim 1, wherein the image sensor comprises a single-junction structure or multi-junction structure.

26. The method of claim 1, wherein the image sensor comprises a backside-illuminated charge coupled device or a backside-illuminated active pixel sensor.

27. The method of claim 26, wherein the insulator substrate is transparent glass.

28. The method of claim 1, wherein forming the anodic bond comprises bonding by means of electrolysis.

29. The method of claim 1, wherein forming the anodic bond and separating the exfoliation layer together comprise transferring the exfoliation layer to the insulator substrate.

30. An image sensor comprising:
an insulator structure;
a semiconductor film;
an anodic bond between the semiconductor film and the insulator structure; and
a plurality of image sensor features proximate to the semiconductor film.

31. The image sensor of claim 30, wherein the insulator has a first ion migration zone, and the semiconductor film respectively has a second ion migration zone.

32. The image sensor of claim 30, wherein the anodic bond region comprises an interface region.

33. The image sensor of claim 32, wherein the interface region comprises a hybrid region and a depletion region.

34. The image sensor of claim 30, further comprising a conductive region between the semiconductor film and the insulator substrate.

35. The image sensor of claim 34, wherein the conductive region comprises a metal-based material or a metal-oxide based material.

36. The image sensor of claim 34, wherein the conductive region comprises one or more of a back contact region and a conducting window region, wherein:
the back contact region comprises aluminum, titanium, nickel, tungsten, indium, molybdenum, gold, platinum, palladium, gallium, tin, antimony, silver, germanium, or a silicide; and
the conducting window region comprises tin-doped indium oxide, aluminum-doped zinc oxide, boron-doped zinc oxide, or carbon nanotubes.

37. The image sensor of claim 30, wherein the semiconductor film comprises an n-type semiconductor layer, a p-type semiconductor layer, or a semiconductor layer having at least one n-type doped region and at least one p-type doped region.

38. The image sensor of claim 30, wherein the semiconductor film comprises an exfoliation layer of a substantially single-crystal donor semiconductor wafer.

39. The image sensor of claim 30, wherein the plurality of image sensor features includes at least one n-type doped region, at least one p-type doped region, at least one conductive region, at least one gate, and circuitry.

40. The image sensor of claim 30, wherein the plurality of image sensor features comprises an epitaxially grown crystalline semiconductor region.

41. The image sensor of claim 30, wherein the image sensor comprises a backside-illuminated charge coupled device or a backside-illuminated active pixel sensor.

42. The image sensor of claim 41, wherein the insulator substrate is transparent glass.

43. A system for the formation of image sensors, the system comprising:
a image sensor handling assembly, and
a image sensor processing assembly,
wherein the image sensor processing assembly comprises a preparing system and a transferring system, wherein the preparing system prepares intermediate structures of the image sensors being handled by the image sensor handling assembly, and the transferring system transfers the intermediate structures to insulator substrates.

44. The system of claim 43, further comprising a bonding system, wherein the bonding system is configured to perform anodic bonding of the insulator substrate to the intermediate structures.

45. The system of claim 43, further comprising a finishing system, wherein the finishing system is configured to perform at least one finishing process selected from a group including scribing, polishing, annealing, cleaning, doping, creating an ohmic contact region, creating a gate, creating circuitry, creating a passivating region, creating an encapsulating region, and adding additional semiconductor material.
